(19) United States
(12) Patent Application Publication
(10) Pub. No.: US 2026/0047304 A1
(43) Pub. Date: Feb. 12, 2026

(54) DISPLAY DEVICE, METHOD FOR FABRICATING THE DISPLAY DEVICE, AND ELECTRONIC DEVICE INCLUDING THE DISPLAY DEVICE

(71) Applicant: Samsung Display Co., Ltd., Yongin-si (KR)

(72) Inventors: Keun Woo PARK, Yongin-si (KR); Min Jae KIM, Yongin-si (KR); Jae Cheol PARK, Yongin-si (KR); Gak Seok LEE, Yongin-si (KR)

(21) Appl. No.: 19/170,800

(22) Filed: Apr. 4, 2025

(30) Foreign Application Priority Data
Aug. 12, 2024 (KR) 10-2024-0107479

(51) Int. Cl. H10K 59/38; H10K 59/80

(52) U.S. Cl. CPC H10K 59/38; H10K 59/873

(57) ABSTRACT

A display device, a method for fabricating the display device and an electronic device including the display device are provided. The display device includes a substrate, a light-emitting element layer on the substrate and defining a plurality of light-emitting areas and a non-light-emitting region, a thin-film encapsulation layer on the light-emitting element layer, a wavelength conversion layer on the thin-film encapsulation layer and including a first wavelength conversion pattern, a second wavelength conversion pattern, a light-transmitting pattern, and a partition wall, and a color filter layer on the wavelength conversion layer, wherein the partition wall includes a first conductive layer, a second conductive layer and a third conductive layer sequentially stacked on one another, and wherein the first conductive layer overlaps the light-emitting areas and the non-light-emitting area, and the second conductive layer and the third conductive layer each overlap the non-light-emitting area.

### CROSS-REFERENCE TO RELATED APPLICATION

The present application claims priority to and the benefit of Korean Patent Application No. 10-2024-0107479, filed on Aug. 12, 2024, in the Korean Intellectual Property Office, the entire disclosure of which is incorporated herein by reference.

### BACKGROUND

### 1. Field

Embodiments of the present disclosure relate to a display device, a method for fabricating the display device, and electronic device including the display device.

### 2. Description of the Related Art

As the information society evolves, the desire and/or demand for display devices is ever increasing. Display devices are employed in various electronic devices, such as smart phones, digital cameras, laptop computers, navigation devices, and/or smart televisions.

Display devices may include or be flat panel display devices such as liquid-crystal display devices, field emission display devices, and/or light-emitting display devices. Light-emitting display devices may be further categorized into organic light-emitting display devices, which use organic light-emitting elements, inorganic light-emitting display devices, which use inorganic light-emitting elements like inorganic semiconductors, and micro light-emitting display devices, which use micro light-emitting elements.

An organic light-emitting element may include two opposing electrodes with an emissive layer in between. Electrons and holes supplied from the two electrodes are recombined in the emissive layer to generate excitons. When these generated excitons transition (decay) from an excited state to the ground state, light is emitted.

Organic light-emitting display devices, which incorporate organic light-emitting elements, do not require a separate light source like a backlight unit like a backlight unit. This results in lower power consumption and allows the devices to be lighter and thinner. Additionally, organic light-emitting displays offer high-quality characteristics such as wide viewing angles, high luminance and contrast, and/or fast response speeds. Consequently, they are gaining attention as the next generation of display devices.

The above information disclosed in this Background section is intended to enhance understanding of the background of the disclosure and may contain information that does not constitute prior art.

### SUMMARY

Aspects of one or more embodiments of the present disclosure are directed toward a display device designed to (that can) simplify processes and improve efficiency, a method of fabricating the display device, and an electronic device including the display device.

Additional aspects will be set forth in part in the description which follows and, in part, will be apparent from the description, or may be learned by practice of the presented embodiments of the disclosure.

According to one or more embodiments of the present disclosure, a display device includes a substrate, a light-emitting element layer arranged on the substrate and defining a plurality of light-emitting areas and a non-light-emitting region, a thin-film encapsulation layer arranged on the light-emitting element layer, a wavelength conversion layer arranged on the thin-film encapsulation layer and including a first wavelength conversion pattern, a second wavelength conversion pattern, a light-transmitting pattern, and a partition wall, and a color filter layer arranged on the wavelength conversion layer, wherein the partition wall includes a first conductive layer, a second conductive layer and a third conductive layer sequentially stacked on one another, and wherein the first conductive layer overlaps the light-emitting areas and the non-light-emitting area, and the second conductive layer and the third conductive layer each overlap the non-light-emitting area.

In one or more embodiments, the first conductive layer may continuously cover the first wavelength conversion pattern, the second wavelength conversion pattern, and the light-transmitting pattern.

In one or more embodiments, the first conductive layer may be in contact with the thin-film encapsulation layer in the non-light-emitting area.

In one or more embodiments, the second conductive layer may overlap the plurality of light-emitting areas and may include openings that define a plurality of light-output portions exposing the first conductive layer.

In one or more embodiments, the third conductive layer may not overlap the light-output portions and/or the light-emitting areas.

In one or more embodiments, each of the first conductive layer and the third conductive layer may include at least one of ITO, IZO, ZnO, ITZO, and/or indium oxide.

In one or more embodiments, the second conductive layer may include at least one of silver, magnesium, aluminum, platinum, lead, gold, nickel, neodymium, iridium, chromium, lithium, and/or calcium.

In one or more embodiments, a thickness of the first conductive layer may be in a range of about 800 Å to about 1,350 Å.

In one or more embodiments, a thickness of the first conductive layer may be larger than a thickness of the third conductive layer.

In one or more embodiments, the display device may further include an organic pattern arranged between the third conductive layer and the color filter layer, wherein a side of the organic pattern protrudes outwardly from a side of the third conductive layer.

In one or more embodiments, the first wavelength conversion pattern may be to convert source light emitted from the light-emitting element layer into light of a first color, the second wavelength conversion pattern may be to convert the source light into light of a second color, and the light-transmitting pattern may be to transmit the source light as it is (e.g., without conversion).

According to one or more embodiments of the present disclosure, a method for fabricating a display device, the method includes preparing a substrate provided with a light-emitting element layer that defines a plurality of light-emitting areas and a non-light-emitting area, and a thin-film encapsulation layer arranged on the light-emitting element layer. The method further includes forming a first wavelength conversion pattern, a second wavelength conversion pattern and a light-transmitting pattern on the thin-film encapsulation layer; sequentially forming a first conductive material layer, a second conductive material layer and a third conductive material layer on the first wavelength conversion pattern, the second wavelength conversion pattern and the light-transmitting pattern; forming a second conductive layer and a third conductive layer by first etching the second conductive material layer and the third conductive material layer; forming a color filter layer on the first conductive material layer and the third conductive material layer; and forming a first conductive layer by second etching the first conductive material layer.

In one or more embodiments, the first etching may include etching the second conductive material layer and the third conductive material layer together.

In one or more embodiments, the first wavelength conversion pattern, the second wavelength conversion pattern and the light-transmitting pattern may be formed by a photo process.

In one or more embodiments, the second etching may include removing the first conductive material layer that is not masked by the color filter layer using the color filter layer as a mask.

According to one or more embodiments of the present disclosure, a display device includes a substrate, a light-emitting element layer, arranged on the substrate and defining a plurality of light-emitting areas and a non-light-emitting region, a thin-film encapsulation layer arranged on the light-emitting element layer, a wavelength conversion layer arranged on the thin-film encapsulation layer and including a first wavelength conversion pattern, a second wavelength conversion pattern, a light-transmitting pattern, and a partition wall, and a color filter layer arranged on the wavelength conversion layer, wherein the partition wall includes a first conductive layer, a second conductive layer and a third conductive layer sequentially stacked on one another, and wherein the first conductive layer is arranged in the light-emitting areas and the non-light-emitting area, and includes grooves overlapping the light-emitting areas, and the second conductive layer and the third conductive layer do not overlap the grooves.

In one or more embodiments, the second conductive layer and the third conductive layer may be arranged between adjacent ones of the first wavelength conversion pattern, the second wavelength conversion pattern and the light transmitting pattern, and may not overlap the light-emitting areas and may overlap the non-light-emitting area.

In one or more embodiments, the grooves of the first conductive layer may not overlap the second conductive layer and the third conductive layer.

In one or more embodiments, a thickness of a portion of the first conductive layer overlapping the second and third conductive layers may be greater than a thickness of another portion of the first conductive layer not overlapping the second and third conductive layers.

In one or more embodiments, the first conductive layer may continuously cover the first wavelength conversion pattern, the second wavelength conversion pattern, and the light-transmitting pattern.

According to one or more embodiments of the present disclosure, a first wavelength conversion pattern, a second wavelength conversion pattern and a light transmitting pattern in a display device may be protected by using a first conductive layer of a partition wall, and it is possible to prevent or reduce color mixing of lights by using a second conductive layer and a third conductive layer of the partition wall. In one or more embodiments, by disposing a color filter layer directly on a wavelength conversion layer, it is possible to improve properties of light traveling from the wavelength conversion layer to the color filter layer.

According to one or more embodiments of the present disclosure, an electronic device includes a display device including a substrate light-emitting element layer arranged on the substrate and defining a plurality of light-emitting areas and a non-light-emitting region, a thin-film encapsulation layer arranged on the light-emitting element layer, a wavelength conversion layer arranged on the thin-film encapsulation layer and including a first wavelength conversion pattern, a second wavelength conversion pattern, a light-transmitting pattern, and a partition wall, and a color filter layer arranged on the wavelength conversion layer, wherein the partition wall includes a first conductive layer, a second conductive layer and a third conductive layer sequentially stacked on one another, and wherein the first conductive layer overlaps the light-emitting areas and the non-light-emitting area, and the second conductive layer and the third conductive layer each overlap the non-light-emitting area.

It should be noted that effects of the present disclosure are not limited to those described above and other effects of the present disclosure will be apparent to those skilled in the art from the following descriptions.

### BRIEF DESCRIPTION OF THE DRAWINGS

The accompanying drawings are included to provide a further understanding of the present disclosure, and are incorporated in and constitute a part of this specification. The drawings illustrate example embodiments of the present disclosure and, together with the description, serve to explain principles of the present disclosure. In the drawings:

FIG. 1 is a plan view of a display device according to one or more embodiments of the present disclosure.

FIG. 2 is a view schematically showing lines included in the display device according to one or more embodiments of the present disclosure.

FIG. 3 is an equivalent circuit diagram of a sub-pixel according to one or more embodiments of the present disclosure.

FIG. 4 is a cross-sectional view schematically showing a display device according to one or more embodiments of the present disclosure.

FIG. 5 is a cross-sectional view schematically showing the display area of the display device according to one or more embodiments of the present disclosure.

FIG. 6 is a cross-sectional view schematically showing a display device according to one or more embodiments of the present disclosure.

FIG. 7 is a plan view showing emission areas of a display device according to one or more embodiments of the present disclosure.

FIG. 8 is a plan view showing the arrangement of a partition wall of a display device according to one or more embodiments of the present disclosure.

FIG. 9-12 are cross-sectional views showing processing steps (e.g., acts or tasks) of a method of fabricating a display device according to one or more embodiments of the present disclosure.

FIG. 13 is a cross-sectional view showing a display device according to one or more embodiments of the present disclosure.

FIG. 14 is a cross-sectional view showing the partition wall and the organic pattern of FIG. 13, according to one or more embodiments of the present disclosure.

FIG. 15-18 are cross-sectional views showing processing steps (e.g., acts or tasks) of a method for fabricating a display device according to one or more embodiments of the present disclosure.

FIG. 19 is a cross-sectional view showing a display device according to one or more embodiments of the present disclosure.

FIG. 20 is a cross-sectional view showing a display device according to one or more embodiments of the present disclosure.

FIG. 21 is a cross-sectional view showing the partition wall of FIG. 20, according to one or more embodiments of the present disclosure.

### DETAILED DESCRIPTION

The present disclosure may be modified in many alternate forms, and thus specific embodiments will be illustrated in the drawings and described in more detail. It should be understood, however, that this is not intended to limit the present disclosure to the particular forms disclosed, but rather, is intended to cover all modifications, equivalents, and alternatives falling within the spirit and scope of the present disclosure.

Hereinafter, example embodiments will be described in more detail with reference to the accompanying drawings. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described.

It will be understood that when an element, such as an area, layer, film, region or portion, is referred to as being “on,” “connected to,” or “coupled to” another element, it can be directly on, connected to, or coupled to the other element, or one or more intervening elements may be present. In contrast, when an element or layer is referred to as being “directly on,” “directly connected to”, “directly coupled to”, or “immediately adjacent to” another element or layer, there are no intervening elements or layers present. In addition, it will also be understood that when an element is referred to as being “between” two elements, it can be the only element between the two elements, or one or more intervening elements may also be present.

Unless otherwise noted, like reference numerals denote like elements throughout the attached drawings and the written description, and thus, duplicative descriptions thereof may not be provided.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

Spatially relative terms, such as “on,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the drawings. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

As used herein, the singular forms “a,” “an” and “the” are intended to include the plural forms as well, unless the context clearly indicates otherwise. It will be further understood that the terms “comprises,” “comprising,” “includes,” “including,” “have,” and “having,” when used in this specification, specify the presence of the stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

As used herein, the term “and/or” includes any and all combinations of one or more of the associated listed items. Unless otherwise apparent from the disclosure, expressions such as “at least one of,” “a plurality of,” “one of,” and other prepositional phrases, when preceding a list of elements, should be understood as including the disjunctive if written as a conjunctive list and vice versa. For example, the expressions “at least one of a, b, or c,” “at least one of a, b, and/or c,” “one selected from the group consisting of a, b, and c,” “at least one selected from among a, b, and c,” “at least one from among a, b, and c,” “one from among a, b, and c”, “at least one of a to c” indicates only a, only b, only c, both a and b, both a and c, both b and c, all of a, b, and c, or variations thereof.

As used herein, the terms “use,” “using,” and “used” may be considered synonymous with the terms “utilize,”“utilizing,”and “utilized,”respectively.

In the present disclosure, when particles are spherical, “diameter” or “size” indicates a particle diameter or an average particle diameter, and when the particles are non-spherical, the “diameter” or “size” indicates a major axis length or an average major axis length. The diameter (or size) of the particles may be measured utilizing a scanning electron microscope or a particle size analyzer. As the particle size analyzer, for example, HORIBA, LA-950 laser particle size analyzer, may be utilized. When the size of the particles is measured utilizing a particle size analyzer, the average particle diameter (or size) is referred to as D50. D50 refers to the average diameter (or size) of particles whose cumulative volume corresponds to 50 vol % in the particle size distribution (e.g., cumulative distribution), and refers to the value of the particle size corresponding to 50% from the smallest particle when the total number of particles is 100% in the distribution curve accumulated in the order of the smallest particle size to the largest particle size.

In the context of the present disclosure and unless otherwise defined, a plan view is an orthographic projection of a three-dimensional object from the position of a horizontal plane through the object. That is, it is a top-down view, showing the layout and spatial relationships of various elements within the object or structure. A plan view based on the direction DR3 refers to a top-down view of the display panel, as if looking directly down onto the surface from above. In this context, DR3 is the direction perpendicular or normal to the plane defined by the first direction DR1 and the second direction DR2. This refers to that in a plan view, the arrangement of sub-pixels, pads, and other components as they are laid out on the substrate can be seen, without any perspective distortion.

Each of the features of the embodiments of the present disclosure may be combined or combined with each other, in part or in whole, and technically various interlocking and driving are possible. Each embodiment may be implemented independently of each other or may be implemented together in an association.

Hereinafter, embodiments of the present disclosure will be described with reference to the accompanying drawings.

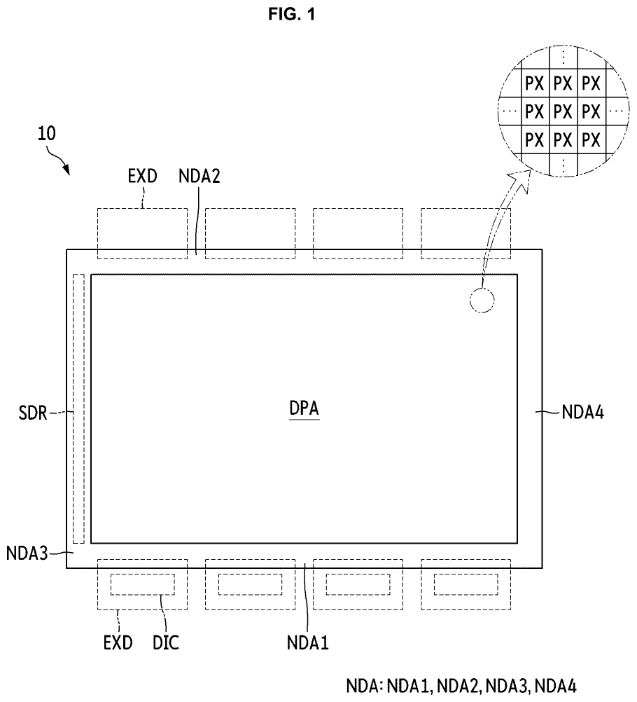

FIG. 1 is a plan view of a display device according to one or more embodiments of the present disclosure.

Referring to FIG. 1, a display device 10 according to one or more embodiments of the present disclosure may be applied to, a smart phone, a mobile phone, a tablet PC, a personal digital assistant (PDA), a portable multimedia player (PMP), a television set, a game machine, a wristwatch-type (kind) electronic device, a head-mounted display, a personal computer monitor, a laptop computer, a car navigation system, a car instrument cluster, a digital camera, a camcorder, an outdoor billboard, an electronic billboard, one or more suitable medical apparatuses, one or more suitable home appliances such as a refrigerator and a laundry machine, Internet of things (IoT) devices, and/or the like. In the following description, a television is described as an example of the display device 10. TV may have a high resolution or ultra-high resolution such as high definition (HD), ultra-high definition (UHD), 4K (having a horizontal display resolution of about 4,000 pixels) and/or 8K (having a horizontal display resolution of about 8,000 pixels).

In one or more embodiments, the display device 10 may be classified by the way in which images are displayed. Examples of the classification of display device 10 may include an organic light-emitting display device (OLED), an inorganic light-emitting display device (inorganic EL), a quantum-dot light-emitting display device (QED), a micro LED display device (micro-LED), a nano LED display device (nano-LED), a plasma display device (PDP), a field emission display device (FED), a cathode ray display device (CRT), a liquid-crystal display device (LCD), an electrophoretic display device (EPD), and/or the like. In the following description, an organic light-emitting display device and an inorganic light-emitting display device will be described as an example of the display device 10, and such light-emitting display devices will be simply referred to as display devices unless it is necessary to discern between them. It is, however, to be understood that the embodiments of the present disclosure are not limited to the organic light-emitting display device or an inorganic light-emitting display device, and one of the above-listed display devices or any other display device suitable, generally utilized and/or generally available in the art may be employed without departing from the scope of the present disclosure.

According to one or more embodiments, the display device 10 may have a rectangular shape, e.g., a rectangular or square shape when viewed from the top (e.g., in a plan view). When the display device 10 is a television, it is oriented such that the longer sides are positioned in the horizontal direction. It should be understood, however, that the present disclosure is not limited thereto. The longer side may be positioned in the vertical direction. In one or more embodiments, the display device 1 may be installed so that the position of the display device is rotatable, e.g., so that the longer sides may be positioned in either the horizontal or vertical direction.

The display device 10 may include a display area DPA and a non-display area NDA. The display area DPA may be an active area where images are displayed. The display area DPA may have, but is not limited to, a rectangular shape similar to the general shape of the display device 10 when viewed from the top (e.g., in a plan view).

The display area DPA may include a plurality of pixels PX. The plurality of pixels PX may be arranged in a matrix. The shape of each of the pixels PX may be, but is not limited to, a rectangle or a square when viewed from the top (e.g., in a plan view). Each of the pixels PX may have a diamond shape having sides inclined with respect to a side of the display device 10. The plurality of pixels PX may include different color pixels PX. For example, the plurality of pixels PX may include, but is not limited to, a red first color pixel PX, a green second color pixel PX, and a blue third color pixel PX. The color pixels PX may be arranged alternately in a RGB stripe pattern or a PenTile® matrix (for example, an RGBG matrix, an RGBG structure, or RGBG matrix structure). PENTILE® is a duly registered trademark of Samsung Display Co., Ltd.

The non-display area NDA may be arranged around the display area DPA. The non-display area NDA may be around (e.g., surround) the display area DPA entirely or partially. The display area DPA may have a rectangular shape, and the non-display area NDA may be arranged to be adjacent to the four sides of the display area DPA. The non-display area NDA may form the bezel of the display device 10.

In the non-display area NDA, a driving circuit or a driving element for driving the display area DPA may be arranged. According to one or more embodiments of the present disclosure, a pad area is arranged on the display substrate of the display device 10 in a first non-display area NDA1 arranged adjacent to a first longer side (the lower side in FIG. 1) of the display device 10 and a second non-display area NDA2 adjacent to a second longer side (the upper side in FIG. 1) of the display device 1. An external device EXD may be mounted on a pad electrode of the pad area. Examples of the external devices EXD may include a connection film, a printed circuit board, a driver chip DIC, a connector, a line connection film, and/or the like. A scan driver SDR formed directly on the display substrate of the display device 10 may be arranged in the third non-display area NDA3 arranged adjacent to a first shorter side of the display device 1 (the left side in FIG. 1). It should be understood, however, that the present disclosure is not limited thereto. The scan driver SDR may be arranged in a fourth non-display area NDA4 adjacent to a second shorter side (right side in FIG. 1) of the display device 10.

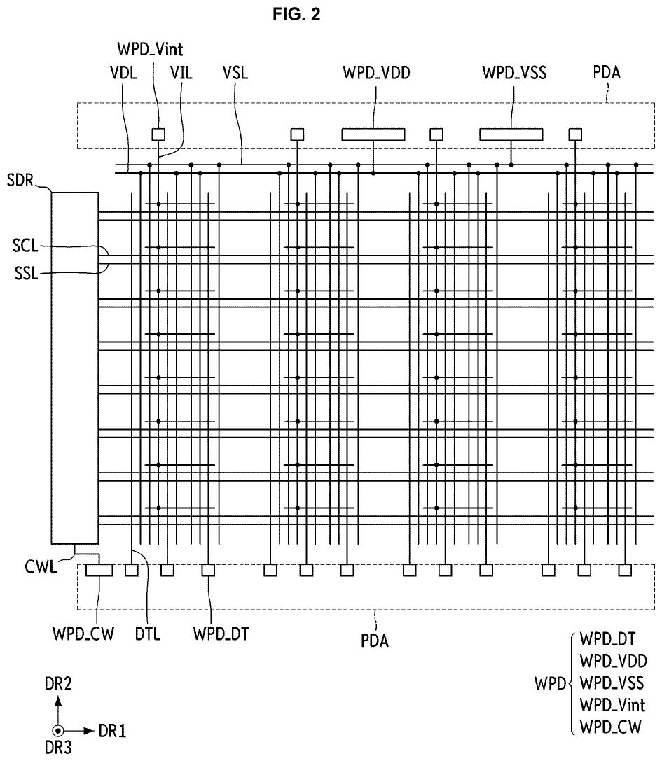

FIG. 2 is a view schematically showing lines included in the display device according to one or more embodiments of the present disclosure.

Referring to FIG. 2, the display device 10 may include a plurality of lines. The plurality of lines may include a scan line SCL, a sensing line SSL, a data line DTL, an initialization voltage line VIL, a first voltage line VDL, a second voltage line VSL, and/or the like. In one or more embodiments, other lines may be further arranged in the display device 10.

The scan line SCL and the sensing line SSL may extend in the first direction DR1. The scan line SCL and the sensing line SSL may be connected to a scan driver SDR. The scan driver SDR may include a driving circuit. The scan driver SDR may be arranged on, but is not limited to, one side of the display area DPA in the first direction DR1. The scan driver SDR may be connected to a signal connection line CWL, and at least one end of the signal connection line CWL may form a pad WPD_CW on a pad area PDA in the non-display area to be connected to an external device.

As used herein, when an element is referred to as being “connected” or “coupled” to another element, it can be directly connected or coupled to the element or intervening elements may be present. In addition, such elements may be understood as a single integrated element and thus one portion thereof is connected to another portion. Moreover, when an element is referred to as being “connected” to another element, it may be in direct contact with the element and/or electrically connected to the element.

The data line DTL and the initialization voltage line VIL may extend in a second direction DR2 crossing the first direction DR1. The initialization voltage line VIL may further include branches as well as the portion extending in the second direction DR2. Each of the first voltage line VDL and the second voltage line VSL may also include portions extending in the second direction DR2 and portions connected thereto and extending in the first direction DR1. The first voltage line VDL and the second voltage line VSL may have, but is not limited to, a mesh structure.

For example, each of the pixels PX of the display device 10 may be connected to at least one data line DTL, the initialization voltage line VIL, the first voltage line VDL, and the second voltage line VSL.

The data line DTL, the initialization voltage line VIL, the first voltage line VDL and the second voltage line VSL may be electrically connected to one or more wire pads WPD. The wire pads WPD may be arranged in the pad area PDA.

According to one or more embodiments of the present disclosure, a wire pad WPD_DT of the data line DTL (hereinafter referred to as a data pad) may be arranged in the pad area PDA on one side of the display area DPA in the second direction DR2, and a wire pad WPD_Vint of the initialization voltage line VIL (hereinafter referred to as the initialization voltage pad), a wire pad WPD_VDD of the first voltage line VDL (hereinafter referred to as the first supply voltage pad), and a wire pad WPD_VSS of the second voltage line VSL (hereinafter referred to as the second supply voltage pad) may be arranged in the pad area PDA located on the other side of the display area DPA in the second direction DR2. As another example, the data pad WPD_DT, the initialization voltage pad WPD_Vint, the first supply voltage pad WPD_VDD, and the second supply voltage pad WPD_VSS may all be arranged in substantially the same area, e.g., in the non-display area NDA on the upper side of the display area DPA. External devices EXD may be mounted on the wire pads WPD. The external devices EXD may be mounted on the wire pads WPD by an anisotropic conductive film, ultrasonic bonding, and/or the like.

Each of the pixels PX or sub-pixels PXn of the display device 10 includes a pixel driving circuit, where n is an integer from 1 to 3. The above-described lines may pass through each of the pixels PX or the periphery thereof to apply a driving signal to the pixel driving circuit. The pixel driving circuit may include transistors and a capacitor. The numbers of transistors and capacitors of each pixel driving circuit may be changed in a variety of ways. According to one or more embodiments of the present disclosure, each of the sub-pixels SPXn of the display device 10 may have a 3T1C structure, i.e., a pixel driving circuit includes three transistors and one capacitor. In the following description, the pixel driving circuit having the 3T1C structure will be described as an example. It is, however, to be understood that the present disclosure is not limited thereto. A variety of modified pixel structures may be employed, such as a 2T1C structure, a 7T1C structure, and/or a 6T1C structure.

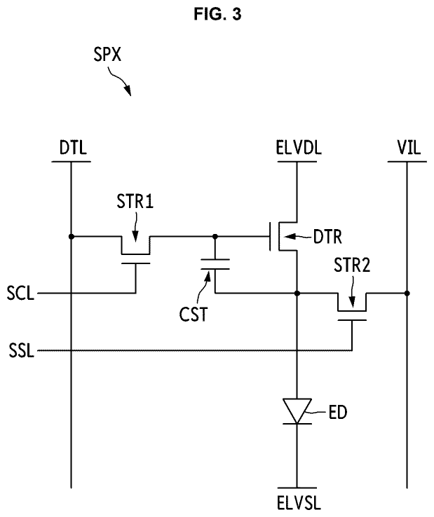

FIG. 3 is an equivalent circuit diagram of a sub-pixel according to one or more embodiments of the present disclosure.

Referring to FIG. 3, each of the sub-pixels SPX of the display device 10 according to one or more embodiments includes three transistors DTR, STR1 and STR2 and one storage capacitor Cst, in addition to a light-emitting element ED.

The light-emitting element ED emits light in proportional to the current supplied through the driving transistor DTR. The light-emitting element ED may be implemented as an inorganic light-emitting diode, an organic light-emitting diode, a micro light-emitting diode, a nano light-emitting diode, and/or the like.

The first electrode (i.e., the anode electrode) of the light-emitting diode ED may be connected to the source electrode of the driving transistor DTR, and the second electrode (i.e., the cathode electrode) thereof may be connected to a second supply voltage line ELVSL, from which a low-level voltage (second supply voltage) is applied, lower than a high-level voltage (first supply voltage) of a first supply voltage line ELVDL.

The driving transistor DTR adjusts a current flowing from the first supply voltage line ELVDL from which the first supply voltage is applied to the light-emitting element ED according to the voltage difference between the gate electrode and the source electrode. The gate electrode of the driving transistor DTR may be connected to a first electrode of the first transistor STR1, the source electrode may be connected to a first electrode of the light-emitting element ED, and the drain electrode may be connected to the first supply voltage line ELVDL from which the first supply voltage is applied.

The first transistor STR1 is turned on by a scan signal of a scan line SCL to connect a data line DTL with the gate electrode of the driving transistor DTR. A gate electrode of the first transistor STR1 may be connected to the scan line SCL, the first electrode thereof may be connected to the gate electrode of the driving transistor DTR, and a second electrode thereof may be connected to the data line DTL.

The second transistor STR2 may be turned on by a sensing signal of a sensing signal line SSL to connect the initialization voltage line VIL to the source electrode of the driving transistor DTR. A gate electrode of the second transistor STR2 may be connected to the sensing signal line SSL, a first electrode thereof may be connected to the initialization voltage line VIL, and a second electrode thereof may be connected to the source electrode of the driving transistor DTR.

According to one or more embodiments of the present disclosure, the first electrode of each of the first and second transistors STR1 and STR2 may be a source electrode while the second electrode thereof may be a drain electrode. It is, however, to be understood that the present disclosure is not limited thereto. The first electrode of each of the first and second switching transistors STR1 and STR2 may be a drain electrode while the second electrode thereof may be a source electrode.

The capacitor CST may be formed between the gate electrode and the source electrode of the driving transistor DTR. The storage capacitor CST stores a voltage difference between the gate voltage and the source voltage of the driving transistor DTR.

The driving transistor DTR and the first and second transistors STR1 and STR2 may be formed as thin-film transistors. In one or more embodiments, although FIG. 3 shows that each of the driving transistor DTR and the first and second switching transistors STR1 and STR2 is implemented as an n-type (kind) MOSFET (metal oxide semiconductor field effect transistor), it is to be noted that the present disclosure is not limited thereto. That is to say, the driving transistor DTR and the first and second switching transistors STR1 and STR2 may be implemented as p-type (kind) MOSFETs, or some of them may be implemented as n-type (kind) MOSFETs while the others may be implemented as p-type (kind) MOSFETs.

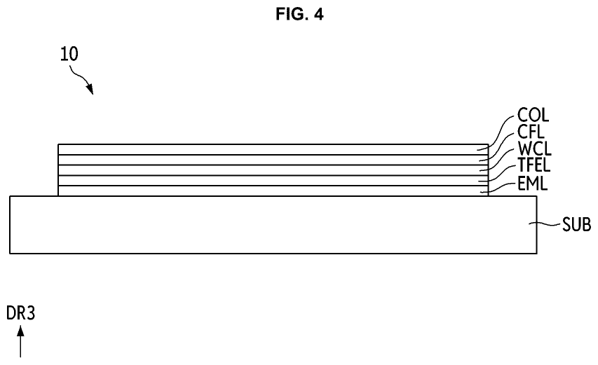

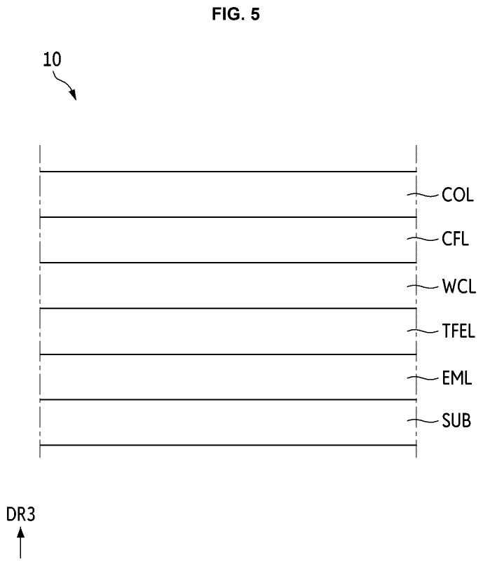

FIG. 4 is a cross-sectional view schematically showing a display device according to one or more embodiments of the present disclosure. FIG. 5 is a cross-sectional view schematically showing the display area of the display device according to one or more embodiments of the present disclosure.

Referring to FIGS. 4 and 5, the display device 10 according to one or more embodiments of the present disclosure may include a substrate SUB, a light-emitting element layer EML, a thin-film encapsulation layer TFEL, a wavelength conversion layer WCL, a color filter layer CFL, and a cover member COL.

The substrate SUB may be an insulating substrate (e.g., an insulator).

The substrate SUB may include a transparent material. For example, the substrate SUB may include a transparent insulating material such as glass and quartz. The substrate SUB may be a rigid substrate. In addition, the substrate SUB is not limited to those described above. The substrate SUB may include a plastic such as polyimide, or may be flexible so that it can be curved, bent, folded or rolled.

The light-emitting element layer EML may be arranged on the substrate SUB. The light-emitting element layer EML may include a plurality of switching elements and a plurality of light-emitting elements ED arranged in each sub-pixel. The switching elements may drive light-emitting elements ED so that the light-emitting elements ED emit light.

The thin-film encapsulation layer TFEL may be arranged on the light-emitting element layer EML. The thin-film encapsulation layer TFEL may include an organic film arranged between a plurality of inorganic films and can protect the light-emitting element layer EML from outside moisture and/or oxygen.

The wavelength conversion layer WCL may be arranged on the thin-film encapsulation layer TFEL. The wavelength conversion layer WCL may convert the wavelength of light emitted from the light-emitting element layer EML to emit red light, green light and/or blue light.

The color filter layer CFL may be arranged on the wavelength conversion layer WCL. The color filter layer CFL can filter light incident from the outside to reduce reflection of external light and to improve the color characteristics of light emitted through the wavelength conversion layer WCL.

The cover member COL may be arranged on the color filter layer CFL. The cover member COL may encapsulate the light-emitting element layer EML together with the substrate SUB. The cover member COL may include a transparent material. For example, the cover member COL may include a transparent insulating material such as a protective film, a coating layer, and/or the like.

Hereinafter, the elements of a display device according to one or more embodiments of the present disclosure will be described in more detail with reference to other drawings.

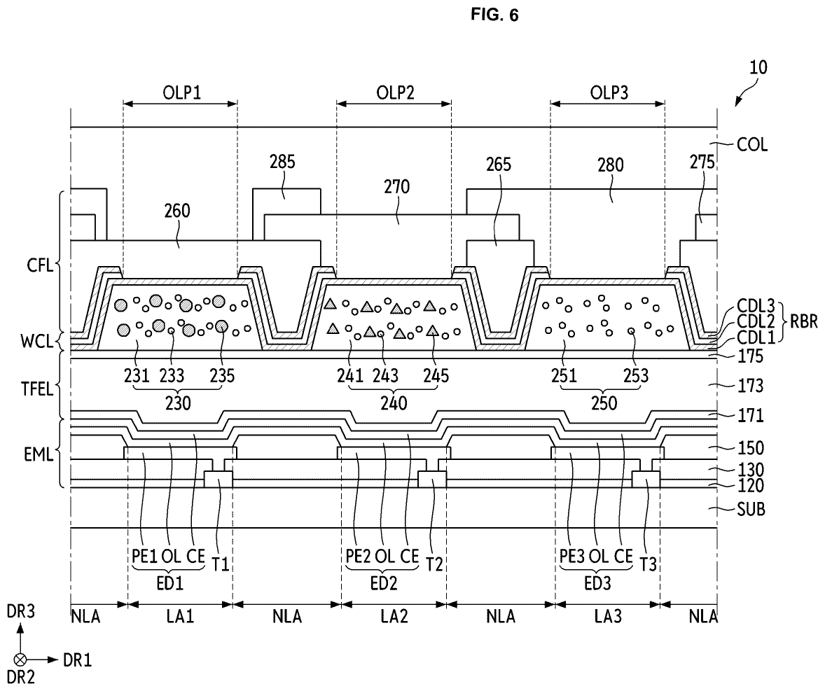

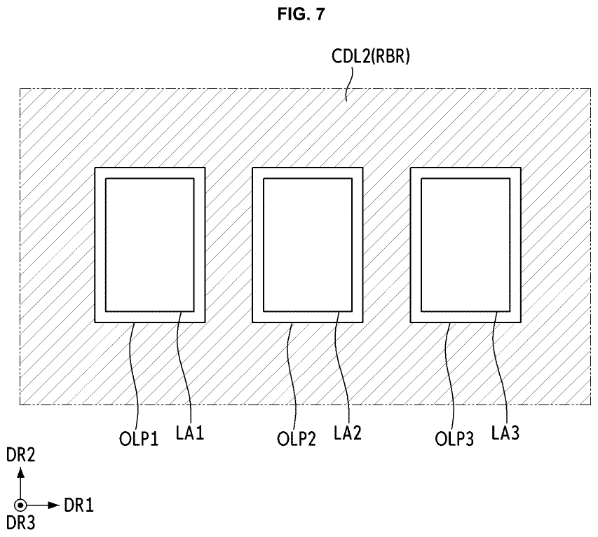

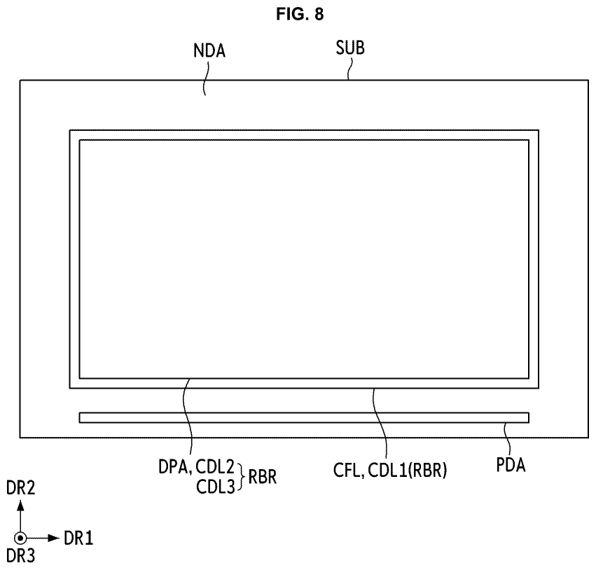

FIG. 6 is a cross-sectional view schematically showing a display device according to one or more embodiments of the present disclosure. FIG. 7 is a plan view showing emission areas of a display device according to one or more embodiments of the present disclosure. FIG. 8 is a plan view showing the arrangement of a partition wall of a display device according to one or more embodiments of the present disclosure.

Referring to FIGS. 6 to 8, the display device 10 according to one or more embodiments of the present disclosure may include a substrate SUB, a light-emitting element layer EML, a thin-film encapsulation layer TFEL, a wavelength conversion layer WCL, a color filter layer CFL, and a cover member COL.

A plurality of light-emitting areas LA1, LA2 and LA3 and a non-light-emitting area NLA may be defined on the substrate SUB. In the light-emitting areas LA1, LA2 and LA3, light generated in the light-emitting elements ED1, ED2 and ED3 may exit (e.g., light may be emitted). In the non-light-emitting area NLA, no light may exit (e.g., no light may be emitted). According to one or more embodiments, a first light-emitting area LA1, a second light-emitting area LA2 and a third light-emitting area LA3 may be arranged repeatedly in this order in the first direction DR1 in the display area DPA.

The first light-emitting area LA1, the second light-emitting area LA2 and the third light-emitting area LA3 may have the same width measured in the first direction DR1. It should be understood, however, that the present disclosure is not limited thereto. The first light-emitting area LA1, the second light-emitting area LA2 and the third light-emitting area LA3 may have different widths measured in the first direction DR1. For example, the width of the third light-emitting area LA3 may be smaller than the width of the second light-emitting area LA2, and the width of the second light-emitting area LA2 may be smaller than the width of the first light-emitting area LA1.

The light-emitting areas LA1, LA2 and LA3 may be to emit light of different colors. According to one or more embodiments of the present disclosure, the first light-emitting area LA1 may be to emit light of a first color, the second light-emitting area LA2 may be to emit light of a second color, and the third light-emitting area LA3 may be to emit light of a third color. According to one or more embodiments of the present disclosure, the light of the first color may be red light with a peak wavelength in the range of approximately (about) 610 nm to 650 nm, the light of the second color may be green light with a peak wavelength in the range of approximately 510 nm to 550 nm, and the light of the third color may be blue light with a peak wavelength in the range of approximately (about) 440 nm to 480 nm. It should be understood, however, that the present disclosure is not limited thereto. The light of the first color may be green light and the light of the second color may be red light.

For example, a display device may include a substrate SUB; a light-emitting element layer EML disposed on the substrate, defining a plurality of light-emitting areas LA1, LA2, and LA3 and a non-light-emitting area NLA; a thin-film encapsulation layer TFEL on the light-emitting element layer; a wavelength conversion layer WCL on the thin-film encapsulation layer, and including a first wavelength conversion pattern, a second wavelength conversion pattern, a light-transmitting pattern, and a partition wall; and a color filter layer CFL disposed on the wavelength conversion layer, wherein the partition wall includes a first conductive layer, a second conductive layer, and a third conductive layer sequentially stacked on one another, and wherein the first conductive layer overlaps with the light-emitting areas LA1, LA2, and LA3 and the non-light-emitting area NLA, and the second and third conductive layers each overlap with the non-light-emitting area NLA.k

On the substrate SUB, switching elements T1, T2 and T3 may be arranged. According to one or more embodiments of the present disclosure, the first switching element T1 may be located in the first emission area LA1 of the substrate SUB, the second switching element T2 may be located in the second emission area LA2, and the third switching element T3 may be located in the third emission area LA3. It is, however, to be understood that the present disclosure is not limited thereto. In one or more embodiments, at least one of the first switching device T1, the second switching device T2 and/or the third switching device T3 may be located in the non-emission area NLA.

According to one or more embodiments of the present disclosure, each of the first switching element T1, the second switching element T2 and the third switching element T3 may be a thin-film transistor including amorphous silicon, polysilicon, and/or an oxide semiconductor. In one or more embodiments, a plurality of signal lines (e.g., gate lines, data lines, power lines, and/or the like) for transmitting signals to the switching elements may be further arranged on the substrate SUB. In one or more embodiments, the switching elements T1, T2 and T3 may include a first insulating layer 120. For example, the first insulating layer 120 may be a gate insulator or an interlayer dielectric film of a thin-film transistor. The gate insulator or the interlayer dielectric film may be made up of a single layer including at least one of silicon oxide (SiOₓ, where, e.g., 0<x≤2), silicon nitride oxide (SiOₓN_{y}, where, e.g., 0<x≤2 and 0<y≤2), and/or silicon nitride (SiₓN_{y}, where, e.g., 0<x≤3 and 0<y≤4), or multiple layers thereof.

A second insulating layer 130 may be arranged over the first switching element T1, the second switching element T2 and the third switching element T3.

According to one or more embodiments of the present disclosure, the second insulating layer 130 may be a planarization film. According to one or more embodiments of the present disclosure, the second insulating layer 130 may be formed as an organic film. For example, the second insulating layer 130 may include an acrylic resin, an epoxy resin, an imide resin, an ester resin, and/or the like.

According to one or more embodiments of the present disclosure, the second insulating layer 130 may include a positive photoresist or a negative photoresist.

The first pixel electrode PE1, the second pixel electrode PE2, and the third pixel electrode PE3 may be arranged on the second insulating layer 130. The first pixel electrode PE1 may be arranged in the first emission area LA1 and may extend at least partially to the non-emission area NLA. The second pixel electrode PE2 may be arranged in the second emission area LA2 and may extend at least partially to the non-emission area NLA. The third pixel electrode PE3 may be arranged in the third emission area LA3 and may extend at least partially to the non-emission area NLA. The first pixel electrode PE1 may be connected to the first switching element T1 through the second insulating layer 130, the second pixel electrode PE2 may be connected to the second switching element T2 through the second insulating layer 130, and the third pixel electrode PE3 may be connected to the third switching element T3 through the second insulating layer 130.

According to one or more embodiments of the present disclosure, the widths or areas of the first pixel electrode PE1, the second pixel electrode PE2 and the third pixel electrode PE3 may be the same as one another. It should be understood, however, that the present disclosure is not limited thereto. The widths or areas of the first pixel electrode PE1, the second pixel electrode PE2 and the third pixel electrode PE3 may be different from one another. For example, the width of the third pixel electrode PE3 may be smaller than the width of the second pixel electrode PE2, and the width of the second pixel electrode PE2 may be smaller than the width of the first pixel electrode PE1 and may be greater than the width of the third electrode PE3. Alternatively, in one or more embodiments, the width of the third pixel electrode PE3 may be smaller than the width of the second pixel electrode PE2, and the width of the second pixel electrode PE3 may be smaller than the width of the first pixel electrode PE1 and may be greater than the width of the third electrode PE3.

The first pixel electrode PE1, the second pixel electrode PE2 and the third pixel electrode PE3 may be reflective electrodes. The first pixel electrode AE1, the second pixel electrode AE2 and the third pixel electrode AE3 may have a stack structure of a material layer having a high work function such as indium tin oxide (ITO), indium zinc oxide (IZO), zinc oxide (ZnO), indium tin zinc oxide (ITZO) and/or indium oxide (In₂O₃), and a reflective material layer such as silver (Ag), magnesium (Mg), aluminum (Al), platinum (Pt), lead (Pb), gold (Au), nickel (Ni), neodymium (Nd), iridium (Ir), chromium (Cr), lithium (Li), calcium (Ca) and/or a (e.g., any suitable) mixture thereof. A material layer having a higher work function may be arranged in a higher layer than a reflective material layer so that it may be closer to an emissive layer OL. The first pixel electrode PE1, the second pixel electrode PE2 and the third pixel electrode PE3 may have, but are not limited to, a multilayer structure of ITO/Mg, ITO/MgF, ITO/Ag, and/or ITO/Ag/ITO.

A pixel-defining layer 150 may be located on the first pixel electrode PE1, the second pixel electrode PE2, and the third pixel electrode PE3. The pixel-defining layer 150 may include an opening exposing the first pixel electrode PE1, an opening exposing the second pixel electrode PE2 and an opening exposing the third pixel electrode PE3, and may define the first light-emitting area LA1, the second light-emitting area LA2, the third light-emitting LA3 and the non-light-emitting area NLA.

For example, a portion of the first pixel electrode PE1 that is not covered by the pixel-defining layer 150 but is exposed may be the first light-emitting area LA1. A portion of the second pixel electrode PE2 that is not covered by the pixel-defining layer 150 but is exposed may be the second light-emitting area LA2. A portion of the third pixel electrode PE3 that is not covered by the pixel-defining layer 150 but is exposed may be the third light-emitting area LA3. The other portions where the pixel-defining layer 150 is located may be the non-light-emitting area NLA.

The pixel-defining layer 150 may include an organic insulating material such as a polyacrylate resin, an epoxy resin, a phenolic resin, a polyamide resin, a polyimide resin, an unsaturated polyester resin, a polyphenylene resin, a poly phenylene sulfide resin, and benzocyclobutene (BCB).

According to one or more embodiments of the present disclosure, the pixel-defining layer 150 may overlap a bank 180 of the wavelength conversion layer WCL, to be described in more detail later. The emissive layer OL may be arranged on the first pixel electrode PE1, the second pixel electrode PE2, and the third pixel electrode PE3. In one or more embodiments where the display device 10 is an organic light-emitting display device, the emissive layer OL may include an organic layer containing an organic material. The organic layer includes an organic emissive layer, and may further include at least one of: a hole injection layer, a hole transport layer, an electronic transport layer and/or an electron injection layer as auxiliary layers in some implementations in order to facilitate light emission.

According to one or more embodiments of the present disclosure, the emissive layer OL may have a tandem structure including a plurality of organic emissive layers overlapping one another in the thickness direction and a charge generation layer arranged therebetween. The organic emissive layer overlapping one another may be to emit either light of the same wavelength or lights of different wavelengths. For example, the overlapping organic emissive layers may include an organic emissive layer that emits light in a green wavelength and an organic emissive layer that emits light in a blue wavelength. According to one or more embodiments, the overlapping organic emissive layers may include an organic emissive layer that emits light in a red wavelength, an organic emissive layer that emits light in a green wavelength, and an organic emissive layer that emits light in a blue wavelength.

According to one or more embodiments of the present disclosure, the emissive layer OL may have the shape of a substantially continuous film arranged across the light-emitting areas LA1, LA2 and LA3 and the non-light-emitting area NLA. In such embodiments, the wavelengths of light emitted from the emissive layer OL may be the same. For example, the emissive layer OL may be to emit blue light, light of a white wavelength, or ultraviolet light from the plurality of emission areas LA1, LA2 and LA3.

The common electrode CE may be arranged on the emissive layer OL. The common electrode CE may be a cathode electrode for each of the light-emitting elements ED1, ED2 and ED3. According to one or more embodiments of the present disclosure, the common electrode CE may be semi-transmissive or transmissive. If the common electrode CE is semi-transmissive, the common electrode CE may include Ag, Mg, Cu, Al, Pt, Pd, Au, Ni, Nd, Ir, Cr, Li, Ca, LiF/Ca, LiF/Al, Mo, Ti and/or a (e.g., any suitable) compound and/or a (e.g., any suitable) mixture thereof, e.g., a mixture of Ag and Mg. Further, if the thickness of the common electrode CE ranges from several tens to several hundred angstroms, the common electrode CE may be semi-transmissive.

When the common electrode CE is transmissive, the common electrode CE may include a transparent conductive oxide (TCO). For example, the common electrode CE may be formed of tungsten oxide (WₓO_{y}, where, e.g., 0<x≤2 and 0<y≤5), titanium oxide (TiO₂), indium tin oxide (ITO), indium zinc oxide (IZO), zinc oxide (ZnO), indium tin zinc oxide (ITZO), MgO (magnesium oxide), and/or the like.

The first pixel electrode PE1, the emissive layer OL and the common electrode CE may form a first light-emitting element ED1, the second pixel electrode PE2, the emissive layer OL and the common electrode CE may form a second light-emitting element ED2, and the third pixel electrode PE3, the emissive layer OL and the common electrode CE may form a third light-emitting element ED3. Each of the first light-emitting element ED1, the second light-emitting element ED2 and the third light-emitting element ED3 may be to emit a source light. The source light may be provided to the wavelength conversion layer WCL. For example, the source light may be, but is not limited to, blue light. For example, it may be white light, or ultraviolet light. The first light-emitting element ED1, the second light-emitting element ED2 and the third light-emitting element ED3 may be organic light-emitting diodes.

The thin-film encapsulation layer TFEL may be arranged on the common electrode CE. The thin-film encapsulation layer TFEL may be located commonly across the first light-emitting area LA1, the second light-emitting area LA2, the third light-emitting area LA3, and the non-emission area NLA. According to one or more embodiments of the present disclosure, the thin-film encapsulation layer TFEL may directly cover the common electrode CE.

According to one or more embodiments of the present disclosure, the thin-film encapsulation layer TFEL may include a first encapsulation layer 171, a second encapsulation layer 173 and a third encapsulation layer 175 sequentially stacked on the common electrode CE.

Each of the first encapsulation layer 171 and the third encapsulation layer 175 may include at least one of: silicon nitride, aluminum nitride, zirconium nitride, titanium nitride, hafnium nitride, tantalum nitride, silicon oxide, aluminum oxide, titanium oxide, tin oxide, cerium oxide, silicon oxynitride (SiON), lithium fluoride, and/or the like. The second encapsulation layer 173 may include an acrylic resin, a methacrylate-based resin, polyisoprene, a vinyl resin, an epoxy resin, a urethane resin, a cellulose resin and/or a perylene resin.

It is to be noted that the structure of the thin-film encapsulation layer TFEL is not limited to the above example. The stack structure of the thin-film encapsulation layer TFEL may be altered in a variety of ways.

The wavelength conversion layer WCL may be arranged on the light-emitting element layer EML including the thin-film encapsulation layer TFEL.

The wavelength conversion layer WCL may include a first wavelength conversion pattern 230, a second wavelength conversion pattern 240, a light-transmitting pattern 250, and a partition wall RBR.

The first wavelength conversion pattern 230, the second wavelength conversion pattern 240 and the light-transmitting pattern 250 may be arranged on the thin-film encapsulation layer TFEL.

The first wavelength conversion pattern 230 may be located on the thin-film encapsulation layer TFEL in the first light-emitting area LA1. The first wavelength conversion pattern 230 may convert or shift the peak wavelength of the incident light into light of another peak wavelength and emit the color-shifted light.

According to one or more embodiments of the present disclosure, the first wavelength conversion pattern 230 may convert the source light provided from the first light-emitting element ED1 into red light having a peak wavelength in the range of approximately (about) 610 nm to 650 nm and to output the light.

The first wavelength conversion pattern 230 may include a first base resin 231 and first wavelength shifters 235 dispersed in the first base resin 231, and may further include first scatterers 233 dispersed in the first base resin 231.

The first base resin 231 may be made of a material having a high light transmittance. According to one or more embodiments of the present disclosure, the first base resin 231 may be made of an organic material. For example, the first base resin 231 may include an organic material such as an epoxy resin, an acrylic resin, a cardo resin, or an imide resin.

The first scatterers 233 may have a refractive index different from that of the first base resin 231 and may form an optical interface with the first base resin 231. For example, the first scatterers 233 may be light scattering particles. The material of the first scatterers 233 is not particularly limited as long as they can scatter at least a portion of the transmitted light. For example, the first scatterers 233 may be metal oxide particles or organic particles. Examples of the metal oxide may include titanium oxide (TiO₂), zirconium oxide (ZrO₂), aluminum oxide (Al₂O₃), indium oxide (In₂O₃), zinc oxide (ZnO), tin oxide (SnO₂), and/or the like. Examples of the material of the organic particles may include an acrylic resin, a urethane resin, and/or the like. The first scatterers 233 can scatter light in random directions regardless of the direction from which the incident light is coming, and without substantially changing the wavelength of the light transmitting from the first wavelength conversion pattern 230.

The first wavelength shifters 235 may convert or shift the peak wavelength of the incident light to another peak wavelength. According to one or more embodiments of the present disclosure, the first wavelength shifters 235 may convert the source light provided from the first light-emitting element ED1, e.g., blue light, into red light having a single peak wavelength in the range of approximately (about) 610 nm to 650 nm.

Examples of the first wavelength shifters 235 may include quantum dots, quantum rods or phosphors. For example, quantum dots may be particulate matter that emits a color as electrons transition from the conduction band to the valence band.

The quantum dots may be a semiconductor nanocrystalline material. The quantum dots have a specific band gap depending on their composition and size, and can absorb light and emit light having an intrinsic wavelength. Examples of the semiconductor nanocrystals of the quantum dots may include Group IV nanocrystals, Groups II-VI compound nanocrystals, Groups III-V compound nanocrystals, Groups IV-VI nanocrystals, and/or a (e.g., any suitable) combination thereof.

The Group II-VI compounds may be selected from the group consisting of: binary compounds selected from the group consisting of CdSe, CdTe, ZnS, ZnSe, ZnTe, ZnO, HgS, HgSe, HgTe, MgSe, MgS and/or a (e.g., any suitable) mixture thereof; ternary compounds selected from the group consisting of InZnP, AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS and/or a (e.g., any suitable) mixture thereof; and quaternary compounds selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe and/or a (e.g., any suitable) mixture thereof.

The Group III-V compounds may be selected from the group consisting of: binary compounds selected from the group consisting of GaN, GaP, GaAs, GaSb, AlN, AlP, AlAs, AlSb, InN, InP, InAs, InSb and/or a (e.g., any suitable) mixture thereof; ternary compounds selected from the group consisting of GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, GaAlNP and/or a (e.g., any suitable) mixture thereof; and quaternary compounds selected from the group consisting of GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb and/or a (e.g., any suitable) mixture thereof.

The Group IV-VI compounds may be selected from the group consisting of: binary compounds selected from the group consisting of SnS, SnSe, SnTe, PbS, PbSe, PbTe and/or a (e.g., any suitable) mixture thereof; ternary compounds selected from the group consisting of SnSeS, SnSeTe, SnSTe, PbSeS, PbSeTe, PbSTe, SnPbS, SnPbSe, SnPbTe and/or a (e.g., any suitable) mixture thereof; and quaternary compounds selected from the group consisting of SnPbSSe, SnPbSeTe, SnPbSTe and/or a (e.g., any suitable) mixture thereof. The group IV elements may be selected from the group consisting of Si, Ge and/or a (e.g., any suitable) mixture thereof. The group IV compounds may be binary compounds selected from among the group consisting of SiC, SiGe and/or a (e.g., any suitable) mixture thereof.

The binary compounds, the ternary compounds or the quaternary compounds may be present in the particles at a substantially uniform concentration, or may be present in the same particles at different concentrations (e.g., partially different concentrations). In one or more embodiments, they may have a core/shell structure in which one quantum dot material surrounds another quantum dot material. At the interface between the core and the shell, the concentration of one or more atoms in the shell may decrease toward the center in a gradient.

According to one or more embodiments of the present disclosure, the quantum dots may have a core-shell structure including a core including the nanocrystals and a shell around (e.g., surrounding) the core. The shell of the quantum-dots may serve as a protective layer for maintaining the semiconductor properties by preventing or reducing chemical denaturation of the core, and/or it may serve as a charging layer for imparting electrophoretic properties to the quantum dots. The shell may be either a single layer or multiple layers. Examples of the shell of the quantum dot may include an oxide of a metal or a non-metal, a semiconductor compound, a combination thereof, and/or the like.

For example, examples of the metal or non-metal oxide may include, but is not limited to, binary compounds such as SiO₂, Al₂O₃, TiO₂, ZnO, MnO, Mn₂O₃, Mn₃O₄, CuO, FeO, Fe₂O₃, Fe₃O₄, CoO, Co₃O₄ and/or NiO or ternary compounds such as MgAl₂O₄, CoFe₂O₄, NiFe₂O₄ and/or CoMn₂O_{4.}

In one or more embodiments, examples of the semiconductor compound may include, but is not limited to, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and/or the like.

The light output from the first wavelength shifters 235 may have a full width at half maximum (FWHM) of the emission wavelength spectrum of approximately (about) 45 nm or less, approximately (about) 40 nm or less, or approximately (about) 30 nm or less. Accordingly, the color purity and color gamut of the colors displayed by the display device 10 can be further improved. In one or more embodiments, the light output from the first wavelength shifters 235 may travel in different directions regardless of the incidence direction of the incident light. In this manner, the side visibility of the first color displayed in the first light-emitting area LA1 can be improved.

Some of the source light provided from the first light-emitting element ED1 may not be converted into red light by the first wavelength shifters 235. However, the light that is not converted into red light may be blocked by the color filter layer CFL arranged thereabove. In contrast, red light converted by the first wavelength conversion pattern 230 passes through the color filter layer CFL and exits to the outside.

The second wavelength conversion pattern 240 may be located on the thin-film encapsulation layer TFEL in the second light-emitting area LA2. The second wavelength-converting pattern 240 may convert or shift the peak wavelength of the incident light into light of another peak wavelength and emit the color-shifted light. According to one or more embodiments of the present disclosure, the second wavelength conversion pattern 240 may convert the source light provided from the second light-emitting element ED2 into green light in the range of approximately (about) 510 nm to 550 nm and output the light.

The second wavelength conversion pattern 240 may include a second base resin 241 and second wavelength shifters 245 dispersed in the second base resin 241, and may further include second scatterers 243 dispersed in the second base resin 241.

The second base resin 241 may be made of a material having a high light transmittance. According to one or more embodiments of the present disclosure, the second base resin 241 may be made of an organic material. The second base resin 241 may be made of the same material as the first base resin 231, or may include at least one of the materials listed above as the examples of the constituent materials of the first base resin 231.

The second wavelength shifters 245 may convert or shift the peak wavelength of the incident light to another peak wavelength. According to one or more embodiments of the present disclosure, the second wavelength shifters 245 may convert the source light having a peak wavelength in the range of 440 nm to 480 nm, e.g., blue light, into green light having a peak wavelength in the range of 510 nm to 550 nm.

Examples of the second wavelength shifters 245 may include quantum dots, quantum rods or phosphors. The second wavelength shifters 245 are substantially identical to the first wavelength shifters 235; and, therefore, redundant descriptions may not be provided. According to one or more embodiments of the present disclosure, the first wavelength shifters 235 and the second wavelength shifters 245 may all be made up of quantum dots. In such embodiments, the particle size (e.g., average particle size) of the quantum dots forming the first wavelength shifters 235 may be greater than the particle size (e.g., average particle size) of the quantum dots forming the second wavelength shifters 245.

The second scatterers 243 may have a refractive index different from that of the second base resin 241 and may form an optical interface with the second base resin 241. For example, the second scatterers 243 may be light scattering particles. The second scatterers 243 are substantially identical to the first scatterers 233 described above; and, therefore, redundant descriptions may not be provided.

The source light output from the second light-emitting element ED2 may be provided to the second wavelength conversion pattern 240. The second wavelength shifters 245 may convert the source light provided from the second light-emitting element ED2 into green light having a peak wavelength in the range of approximately (about) 510 nm to 550 nm and output the light.

Some of the source light may not be converted into green light by the second wavelength shifters 245 and may pass through the second wavelength conversion pattern 240. However, light that is not converted to green light may be blocked by the color filter layer CFL. In contrast, green light converted by the second wavelength conversion pattern 240 passes through the color filter layer CFL and exits to the outside.

The light-transmitting pattern 250 may be arranged on the thin-film encapsulation layer TFEL. The light-transmitting pattern 250 may be in line with (overlap) the third light-emitting area LA3. The light-transmitting pattern 250 may be to transmit incident light. If the source light provided from the third light-emitting element ED3 is blue light, the blue source light may pass through the light-transmitting pattern 250.

According to one or more embodiments of the present disclosure, the light-transmitting pattern 250 may include a third base resin 251 and may further include third scatterers 253 dispersed in the third base resin 251.

The third base resin 251 may be made of a material having a high light transmittance. According to one or more embodiments of the present disclosure, the third base resin 251 may be made of an organic material. The third base resin 251 may be made of the same material as the first base resin 231 or the second base resin 241, or may include at least one of the materials listed above as the examples of the constituent materials of the first base resin 231.

The third scatterers 253 may have a refractive index different from that of the third base resin 251 and may form an optical interface with the third base resin 251. The third scatterers 253 are substantially identical to the first scatterers 233 described above; and, therefore, redundant descriptions may not be provided.

According to one or more embodiments of the present disclosure, the first wavelength conversion pattern 230, the second wavelength conversion pattern 240 and the light-transmitting pattern 250 may be formed via a patterning process, and may be formed by, for example, applying a photosensitive material, and exposing and developing the photosensitive material.

The partition wall RBR may be arranged on the first wavelength conversion pattern 230, the second wavelength conversion pattern 240, the light-transmitting pattern 250 and the thin-film encapsulation layer TFEL. The partition wall RBR may allow for transmission of light in the light-emitting areas LA1, LA2 and LA3 and may block or reduce the transmission of light in the non-light-emitting area NLA.

The partition wall RBR may include a first conductive layer (e.g., conductor) CDL1, a second conductive layer CDL2 and a third conductive layer CDL3 sequentially stacked in a third direction DR3.

The first conductive layer CDL1 may be arranged on the first wavelength conversion pattern 230, the second wavelength conversion pattern 240, the light-transmitting pattern 250 and the thin-film encapsulation layer TFEL. The first conductive layer CDL1 may be arranged to continuously cover the first wavelength conversion pattern 230, the second wavelength conversion pattern 240, and the light-transmitting pattern 250. For example, the first conductive layer CDL1 may be in contact with the upper and side surfaces of the first wavelength conversion pattern 230, the second wavelength conversion pattern 240 and the light-transmitting pattern 250 to completely cover the first wavelength conversion pattern 230, the second wavelength conversion pattern 240 and the light-transmitting pattern 250. The first conductive layer CDL1 may be in contact with the thin-film encapsulation layer TFEL in the non-light-emitting area NLA. For example, the first conductive layer CDL1 may be in contact with the upper surface of the third encapsulation layer 175 of the thin-film encapsulation layer TFEL.

The first conductive layer CDL1 may work as a capping layer. For example, the first conductive layer CDL1 may include a transparent conductive layer and may work as a capping layer that protects the first wavelength conversion pattern 230, the second wavelength conversion pattern 240 and the light-transmitting pattern 250. The first conductive layer CDL1 may cover the first wavelength conversion pattern 230, the second wavelength conversion pattern 240 and the light-transmitting pattern 250, thereby preventing or reducing the likelihood of the first wavelength conversion pattern 230, the second wavelength conversion pattern 240 and the light-transmitting pattern 250 being damaged in subsequent processes.

The first conductive layer CDL1 may include a transparent conductive material. The transparent conductive material may include, for example, at least one of indium tin oxide (ITO), indium zinc oxide (IZO), zinc oxide (ZnO), indium tin zinc oxide (ITZO), and indium oxide (In₂O₃). In one or more embodiments, the first conductive layer CDL1 may include ITO. ITO exhibits moisture permeability close to that of an inorganic film such as SiON, and thus may be more suitable for a protective function. For example, ITO is not highly permeable, and can prevent or reduce moisture from permeating into the first wavelength conversion pattern 230, the second wavelength conversion pattern 240 and the light-transmitting pattern 250, thus protecting those layers.

The first conductive layer CDL1 may include a transparent conductive layer to transmit light. The first conductive layer CDL1 may overlap the light-emitting areas LA1, LA2 and LA3 and may be to transmit light output through the first wavelength conversion pattern 230, the second wavelength conversion pattern 240 and the light-transmitting pattern 250. The first conductive layer CDL1 may have, but is not limited to, a thickness of 800 to 1,350 Å in order to allow for the transmission of light.

The second conductive layer CDL2 may be arranged on the first conductive layer CDL1, and may not overlap the light-emitting areas LA1, LA2 and LA3 but may overlap the non-light-emitting area NLA. The second conductive layer CDL2 may be arranged to cover the side surfaces and a portion of the upper surface of each of the first wavelength conversion pattern 230, the second wavelength conversion pattern 240 and the light-transmitting pattern 250.

The second conductive layer CDL2 may define light-output portions OLP1, OLP2 and OLP3 in line with the first wavelength conversion pattern 230, the second wavelength conversion pattern 240 and the light-transmitting pattern 250, respectively. For example, the second conductive layer CDL2 may include a plurality of openings exposing the first conductive layer CDL1 thereunder, and the plurality of openings may be defined as the light-output portions OLP1, OLP2 and OLP3.

The light-output portions OLP1, OLP2 and OLP3 may include a first light-output portion OLP1, a second light-output portion OLP2 and a third light-output portion OLP3. The first light-output portion OLP1 may be in line with (may overlap) the first wavelength conversion pattern 230 and the first light-emitting area LA1. The second light-output portion OLP2 may be in line with (may overlap) the second wavelength conversion pattern 240 and the second light-emitting area LA2. The third light-output portion OLP3 may be in line with (may overlap) the light-transmitting pattern 250 and the third light-emitting area LA3. The size or area of the light-output portions OLP1, OLP2 and OLP3 may be larger than the size or area of the light-emitting areas LA1, LA2 and LA3. For example, the size or area of the first light-output portion OLP1 may be larger than the size or area of the first light-emitting area LA1, the size or area of the second light-output portion OLP2 may be larger than the size or area of the second light-emitting area LA2, and the size or area of the third light-output portion OLP3 may be larger than the size or area of the third light-emitting area LA3.

The second conductive layer CDL2 may be a reflective layer that reflects light. The second conductive layer CDL2 may include a reflective material to reflect light output from the first wavelength conversion pattern 230, the second wavelength conversion pattern 240, and the light-transmitting pattern 250. For example, the second conductive layer CDL2 may be arranged between adjacent ones of the first wavelength conversion pattern 230, the second wavelength conversion pattern 240 and the light-transmitting pattern 250 to prevent or reduce color mixing between the adjacent light-emitting areas.

The second conductive layer CDL2 may include a reflective material. The reflective material may include, for example, at least one of silver (Ag), magnesium (Mg), aluminum (Al), platinum (Pt), lead (Pb), gold (Au), nickel (Ni), neodymium (Nd), iridium (Ir), chromium (Cr), lithium (Li), and/or calcium (Ca). The second conductive layer CDL2 may have, but is not limited to, a thickness of 2,000 to 3,000 Å in order for the second conductive layer CDL2 to have reflective properties.

The third conductive layer CDL3 may be arranged on the second conductive layer CDL2. The third conductive layer CDL3 may not overlap the light-emitting areas LA1, LA2 and LA3 but may overlap the non-light-emitting area NLA. The third conductive layer CDL3 may be arranged to cover the side surfaces and a portion of the upper surface of each of the first wavelength conversion pattern 230, the second wavelength conversion pattern 240 and the light-transmitting pattern 250. As described in more detail below, as the third conductive layer CDL3 is etched together with the second conductive layer CDL2, the third conductive layer CDL3 may not overlap any of the light-output portions OLP1, OLP2 and OLP3.

The third conductive layer CDL3 may be arranged on the second conductive layer CDL2 to protect the second conductive layer CDL2. The third conductive layer CDL3 may be formed to have a size substantially equal to that of the second conductive layer CDL2. For example, the sides of the third conductive layer CDL3 may be aligned and coordinated with the sides of the second conductive layer CDL2.

The third conductive layer CDL3 may include the same transparent conductive material as the above-described first conductive layer CDL1. For example, the third conductive layer CDL3 may include indium tin oxide (ITO), indium zinc oxide (IZO), zinc oxide (ZnO), indium tin zinc oxide (ITZO), indium oxide (In₂O₃), and/or the like. In one or more embodiments, the third conductive layer CDL3 may include ITO. The third conductive layer CDL3 may have, but is not limited to, a thickness of 100 to 200 Å.

According to one or more embodiments of the present disclosure, the thickness of the first conductive layer CDL1 may be greater than the thickness of the third conductive layer CDL3. The thickness of the first conductive layer CDL1 may be greater than the thickness of the third conductive layer CDL3 in order to avoid being etched during the process of etching the third conductive layer CDL3 and the second conductive layer CDL2.

As shown in FIG. 8, the above-described partition wall RBR may be arranged in the display area DPA and the non-display area NDA. The first conductive layer CDL1 of the partition wall RBR may be arranged in the display area DPA and the non-display area NDA and may overlap the display area DPA and the non-display area NDA. The second conductive layer CDL2 and the third conductive layer CDL3 may be arranged in the display area DPA (see, e.g., the display area DPA in FIG. 8) but not in the non-display area NDA (see, e.g., the display area DPA and non-display area NDA in FIG. 8), and thus may not overlap the non-display area NDA.

As described in more detail below, the second conductive layer CDL2 and the third conductive layer CDL3 may be formed on the display area DPA via a patterning process. In contrast, the first conductive layer CDL1 is formed on the entirety of the substrate SUB, and is etched using the color filter layer CFL as a mask after the color filter layer CFL has been fabricated. Accordingly, the first conductive layer CDL1 may be arranged in the display area DPA and the non-display area NDA where the color filter layer CFL is arranged.

Referring back to FIG. 6, the color filter layer CFL may be arranged on the wavelength conversion layer WCL. The color filter layer CFL may include a first color filter 260, a second color filter 270, and a third color filter 280. In one or more embodiments, the color filter layer CFL may include a first color pattern 265, a second color pattern 275, and a third color pattern 285.

The first color filter 260 may be arranged on the partition wall RBR and the first wavelength conversion pattern 230, and may be in line with (overlap) the first wavelength conversion pattern 230 and the first light-emitting area LA1. The first color pattern 265 may be spaced and/or apart (e.g., spaced apart or separated) from the first color filter 260 and may be in line with the non-light-emitting area NLA and the partition wall RBR.

The first color filter 260 and the first color pattern 265 may selectively transmit light of the first color (e.g., red light) and may block (or reduce) and/or absorb light of the second color (e.g., green light) and light of the third color (e.g., blue light). According to one or more embodiments, the first color filter 260 may be a red color filter and may include a red colorant such as a red dye and/or a red pigment. As used herein, the term colorant encompasses a dye as well as a pigment.

The second color filter 270 may be arranged on the partition wall RBR and the first color pattern 265. The second color filter 270 may be in line with (may overlap) the second wavelength conversion pattern 240 and the second light-emitting area LA2. According to one or more embodiments, one side of the second color filter 270 may be arranged in the non-light-emitting area NLA and overlap the adjacent first color filter 260. The opposite side of the second color filter 270 may be arranged in the non-light-emitting area NLA and overlap the first color pattern 265. The second color pattern 275 may be spaced and/or apart (e.g., spaced apart or separated) from the second color filter 270 and may be in line with (may overlap) the non-light-emitting area NLA. The second color pattern 275 may overlap the first color filter 260 in the non-light-emitting area NLA.

The second color filter 270 and the second color pattern 275 may selectively transmit light of the second color (e.g., green light) and may block or reduce and absorb light of the first color (e.g., red light) and light of the third color (e.g., blue light). For example, the second color filter 270 may be a green color filter and may include a green colorant such as a green dye and/or a green pigment.

The third color filter 280 may be arranged on the partition wall RBR and the second color pattern 275. The third color filter 280 may be in line with (may overlap) the light-transmitting pattern 250 and the third light-emitting area LA3. According to one or more embodiments, one side of the third color filter 280 may be arranged in the non-light-emitting area NLA and overlap the adjacent second color filter 270 and the first color pattern 265. In one or more embodiments, the opposite side of the third color filter 280 may be arranged in the non-light-emitting area NLA and overlap the adjacent first color filter 260 and the second color pattern 275. The third color pattern 285 may be spaced and/or apart (e.g., spaced apart or separated) from the third color filter 280 and may be arranged in line with the non-light-emitting area NLA. The third color pattern 285 may overlap with the first color filter 260 and the second color filter 270 in the non-light-emitting area NLA.

The third color filter 280 may selectively transmit light of the third color (e.g., blue light) that is the source light and may block (or reduce) and/or absorb light of the first color (e.g., red light) and light of the second color (e.g., green light). For example, the third color filter 280 may be a blue color filter and may include a blue colorant such as a blue dye and/or a blue pigment.

As described above, the first to third color filters 260, 270 and 280 and the first to third color patterns 265, 275 and 285 overlap each other in the non-light-emitting area NLA to block (or reduce) and/or absorb light. For example, in the non-light-emitting area NLA arranged on one side of the second light-emitting area LA2, the first color filter 260, the second color filter 270 and the third color pattern 285 overlap one another, and in the non-light-emitting area NLA arranged on the opposite side of the second light-emitting area LA2, the first color pattern 265, the second color filter 270 and the third color filter 280 may overlap one another.

According to one or more embodiments, the color filter layer CFL may be arranged directly on the wavelength conversion layer WCL. For example, the gap between the color filter layer CFL and the wavelength conversion layer WCL may not be provided, thereby improving properties of light traveling from the wavelength conversion layer WCL to the color filter layer CFL. For example, a bottom surface of the color filter layer CFL may be in direct contact with a top surface of the wavelength conversion layer WCL in order to reduce the distance light has to travel between the two layers, thus improving light efficiency and output.

The cover member COL may be arranged on the color filter layer CFL. The cover member COL can protect the underlying elements. The cover member COL may include a cover glass, a protective film, or an organic coating layer. For example, if (e.g., when) the cover member COL includes a cover glass or a protective film, an adhesive layer or a filling layer may be further arranged between the cover member COL and the color filter layer CFL. It is, however, to be understood that the present disclosure is not limited thereto.

In the display device according to the above-described embodiments, it is possible to protect the first wavelength conversion pattern 230, the second wavelength conversion pattern 240 and the light-transmitting pattern 250 by using the first conductive layer CDL1 of the partition wall RBR, and to prevent or reduce color mixing of lights by using the second conductive layer CDL2 and the third conductive layer CDL3. In one or more embodiments, by disposing the color filter layer CFL directly on the wavelength conversion layer WCL, it is possible to improve the properties of light traveling from the wavelength conversion layer WCL to the color filter layer CFL.

Hereinafter, a method of fabricating a display device according to one or more embodiments of the present disclosure will be described with reference to the drawings.

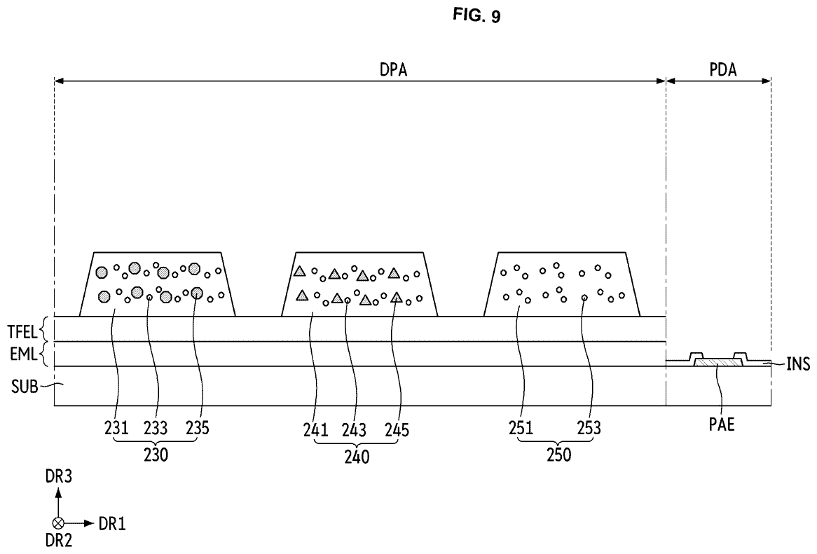

FIGS. 9 to 12 are cross-sectional views showing processing steps of a method of fabricating a display device according to one or more embodiments of the present disclosure. In the following description, the process of fabricating the wavelength conversion layer WCL and the color filter layer CFL of FIG. 6 is mainly shown, along with the process of fabricating the pad area PDA.

Initially, referring to FIG. 9, a substrate SUB is prepared. On the substrate SUB, a light-emitting element layer EML and a thin-film encapsulation layer TFEL may be provided in a display area DPA, and a pad electrode PAE and a pad insulating layer INS may be provided in a pad area PDA. For example, the light-emitting element layer EML and the thin-film encapsulation layer TFEL may be sequentially formed on the substrate SUB, and the pad electrode PAE and the pad insulating layer INS may be formed together with the light-emitting element layer EML. Although each of the light-emitting element layer EML and the thin-film encapsulation layer TFEL is a single layer in the example shown in the drawings, the light-emitting element layer EML and the thin-film encapsulation layer TFEL shown in FIG. 6 may be employed.

Subsequently, a first wavelength conversion pattern 230, a second wavelength conversion pattern 240 and a light-transmitting pattern 250 are formed on the thin-film encapsulation layer TFEL. For example, the light-transmitting pattern 250, the second wavelength conversion pattern 240 and the first wavelength conversion pattern 230 may be formed in this order. The first wavelength conversion pattern 230, the second wavelength conversion pattern 240 and the light-transmitting pattern 250 may each be formed by a photo process. For example, a third base resin 251 mixed with third scatterers 253 is applied on the thin-film encapsulation layer TFEL, and then the light-transmitting pattern 250 may be formed through exposure and development processes. The first wavelength conversion pattern 230, the second wavelength conversion pattern 240 and the light-transmitting pattern 250 may each be formed by a photo process.

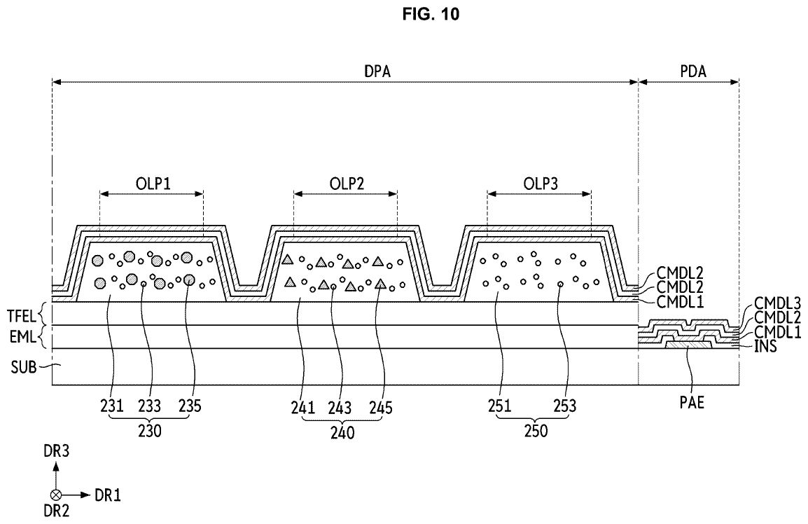

Subsequently, referring to FIG. 10, a first conductive material layer CMDL1, a second conductive material layer CMDL2, and a third conductive material layer CMDL3 are sequentially stacked on the substrate SUB. The first conductive material layer CMDL1, the second conductive material layer CMDL2 and the third conductive material layer CMDL3 may be stacked on the entirety of the substrate SUB and formed in the display area DPA and the pad area PDA. The first conductive material layer CMDL1, the second conductive material layer CMDL2 and the third conductive material layer CMDL3 may be formed by chemical vapor deposition or physical vapor deposition, and/or may be formed by, for example, sputtering.

The first conductive material layer CMDL1 may include a transparent conductive material may include, for example, at least one of indium tin oxide (ITO), indium zinc oxide (IZO), zinc oxide (ZnO), indium tin zinc oxide (ITZO), and/or indium oxide (In₂O₃). The first conductive material layer CMDL1 may have a thickness of 800 to 1,350 Å.

The second conductive material layer CMDL2 may include a reflective material, and may include, for example, at least one of silver (Ag), magnesium (Mg), aluminum (Al), platinum (Pt), lead (Pb), gold (Au), nickel (Ni), neodymium (Nd), iridium (Ir), chrome (Cr), lithium (Li), and/or calcium (Ca). The second conductive material layer CMDL2 may have a thickness of 2,000 to 3,000 Å.

The third conductive material layer CMDL3 may include a transparent conductive material may include, for example, at least one of indium tin oxide (ITO), indium zinc oxide (IZO), zinc oxide (ZnO), indium tin zinc oxide (ITZO), and/or indium oxide (In₂O₃). The third conductive layer CMDL3 may have a thickness of 100 to 200 Å, and may have a thickness less than the thickness of the first conductive material layer CMDL1.

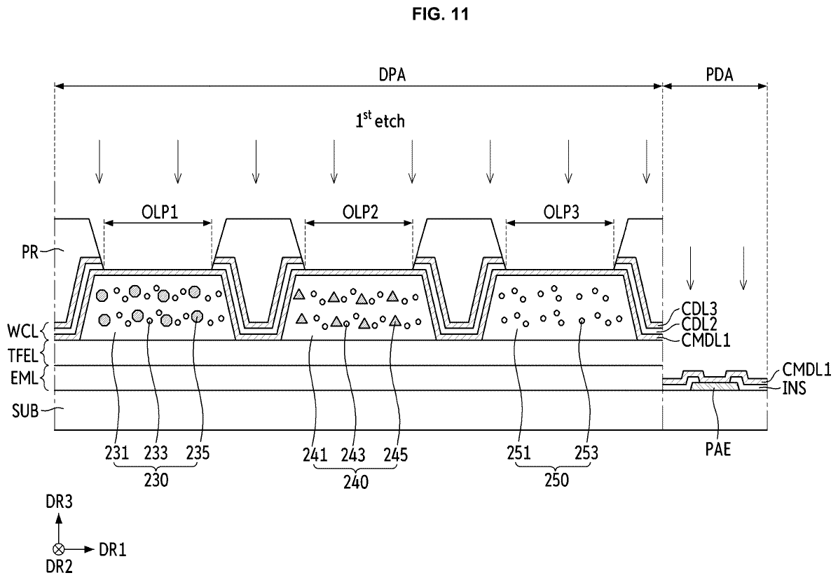

Subsequently, referring to FIG. 11, a mask pattern PR is formed on the third conductive material layer CMDL3. The mask pattern PR may be formed in the display area DPA, and may be formed between adjacent ones of the first wavelength conversion pattern 230, the second wavelength conversion pattern 240, and the light-transmitting pattern 250.

Subsequently, the second conductive material layer CMDL2 and the third conductive material layer CMDL3 are subject to a first etching using the mask pattern PR (1^{st} etch). The first etching (1^{st} etch) may etch the second conductive material layer CMDL2 and the third conductive material layer CMDL3 together, and may use a first etchant for such etching. The first etchant may have different etch rates for the second conductive material layer CMDL2 and for the third conductive material layer CMDL3. For example, the etch rate for the second conductive material layer CMDL2 may be greater than the etch rate for the third conductive material layer CMDL3. According to one or more embodiments of the present disclosure, the etch rate for the second conductive material layer CMDL2 may be at least 150 times faster than the etch rate for the third conductive material layer CMDL3.

In the first etching (1^{st} etch), the second conductive material layer CMDL2 and the third conductive material layer CMDL3 arranged in the pad area PDA are all etched and removed. In addition, in one or more embodiments, the second conductive material layer CMDL2 and the third conductive material layer CMDL3 arranged in the non-display area NDA excluding the display area DPA may also be all etched and removed.

The second conductive material layer CMDL2 and the third conductive material layer CMDL3 are formed into the second conductive layer CDL2 and the third conductive layer CDL3, respectively, by the first etching (1^{st} etch) process. The second conductive layer CDL2 and the third conductive layer CDL3 (e.g., openings in the second conductive layer CDL2 and the third conductive layer CDL3) form and/or define first to third light-output portions OLP1, OLP2 and OLP3 that expose the first conductive material layer CMDL1 thereunder.

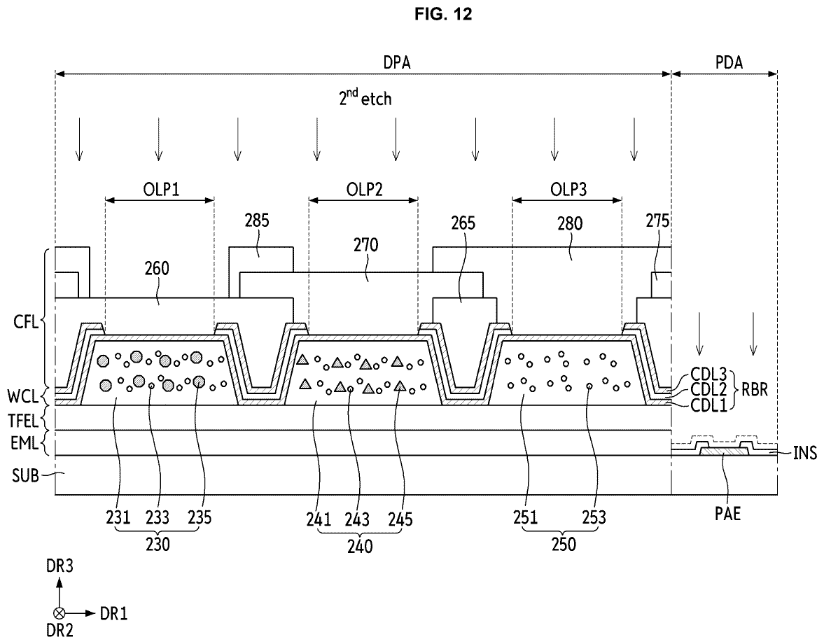

Subsequently, referring to FIG. 12, a color filter layer CFL is formed in the display area DPA. For example, a first color filter 260 and a first color pattern 265, a second color filter 270 and a second color pattern 275, and a third color filter 280 and a third color pattern 285 are sequentially formed on the first conductive material layer CMDL1, the second conductive layer CDL2 and the third conductive layer CDL3. The first color filter 260 is formed to overlap the first wavelength conversion pattern 230, the second color filter 270 is formed to overlap the second wavelength conversion pattern 240, and the third color filter 280 is formed to overlap the light-transmitting pattern 250.

Subsequently, the first conductive material layer CMDL1 formed in the non-display area NDA including the pad area PDA is subjected to second etching (2^{nd} etch). The second etching (2^{nd} etch) may use a second etchant capable of etching the first conductive material layer CMDL1. The second etchant can etch the first conductive material layer CMDL1 and the third conductive layer CDL3 but not the second conductive layer CDL2.

In the second etching process, the color filter layer CFL formed in the display area DPA works as a mask, so that the first conductive material layer CMDL1 and the third conductive layer CDL3 arranged in the display area DPA are not etched. In contrast, the first conductive material layer CMDL1 arranged in the pad area PDA that is not masked by the color filter layer CFL may be removed to expose the pad electrode PAE. In one or more embodiments, because the color filter layer CFL may partially extend (e.g., part of the color filter layer CFL may extend) to the non-display area NDA around the display area DPA, the first conductive material layer CMDL1 masked by the color filter layer CFL remains without being etched. Accordingly, the first conductive material layer CMDL1 that is not removed in the second etching process (2^{nd} etch) is formed into the first conductive layer CDL1.

Through the second etching process, the partition wall RBR is formed by the sequentially stacking of the first conductive layer CDL1, the second conductive layer CDL2 and the third conductive layer CDL3, and the wavelength conversion layer WCL including the first wavelength conversion pattern 230, the second wavelength conversion pattern 240, the light-transmitting pattern 250 and the partition wall RBR can be fabricated. The first conductive layer CDL1 of the partition wall RBR may work as a capping layer for protecting the first wavelength conversion pattern 230, the second wavelength conversion pattern 240 and the light-transmitting pattern 250, thereby preventing or reducing the likelihood of the first wavelength conversion pattern 230, the second wavelength conversion pattern 240 and the light-transmitting pattern 250 being damaged.

In one or more embodiments, a cover member such as a cover window and a protective film may be further formed on the color filter layer CFL.

Hereinafter, a display device according to one or more embodiments of the present disclosure will be described with reference to other drawings.

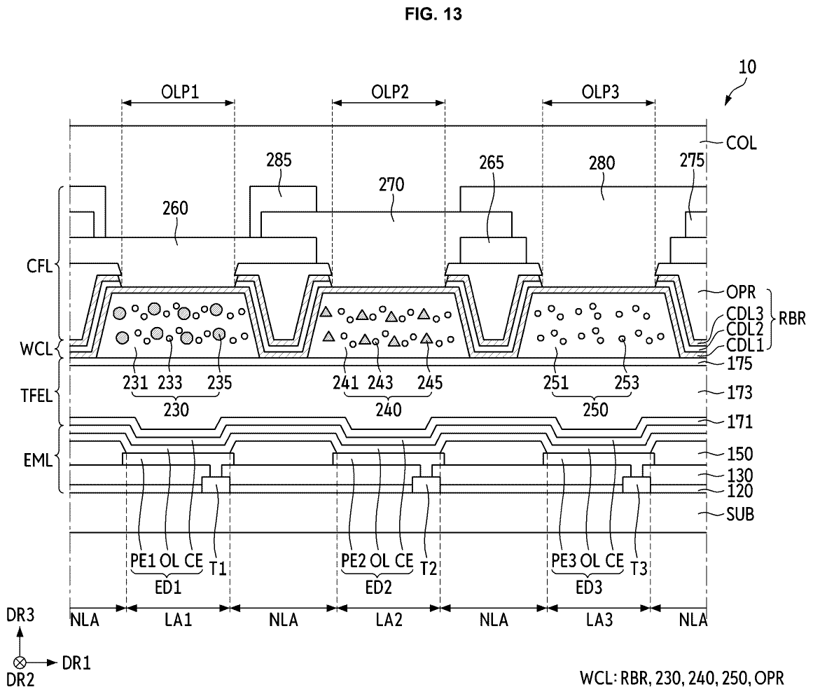

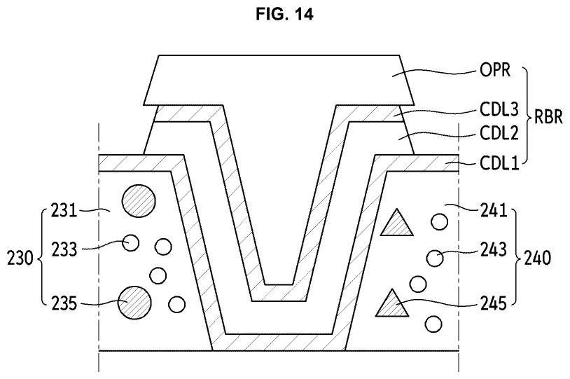

FIG. 13 is a cross-sectional view showing a display device according to one or more embodiments of the present disclosure. FIG. 14 is a cross-sectional view showing the partition wall and the organic pattern of FIG. 13, according to one or more embodiments of the present disclosure.

The embodiment of FIGS. 13 and 14 is different from the above-described embodiment of FIGS. 5 to 9 in that an organic pattern OPR is further arranged between the partition wall RBR and the color filter layer CFL. The following description will focus on the difference and redundant descriptions may not be provided.

The wavelength conversion layer WCL may include the first wavelength conversion pattern 230, the second wavelength conversion pattern 240, the light-transmitting pattern 250, the partition wall RBR, and the organic pattern OPR.

The organic pattern OPR may be arranged between the color filter layer CFL and the partition wall RBR. For example, the organic pattern OPR may be arranged between the color filters 260, 270 and 280 and the third conductive layer CDL3 of the partition wall RBR. The organic pattern OPR may not overlap the light-output portions OLP1, OLP2 and OLP3 and the light-emitting areas LA1, LA2 and LA3, but may overlap the non-light-emitting area NLA.

The organic pattern OPR may be arranged in such a shape that the steps formed by the partition wall RBR are filled with the organic pattern OPR in the non-light-emitting area NLA. For example, the steps of the third conductive layer CDL3 may be filled with the organic pattern ORP to provide a flat upper surface. By filling the steps of the partition wall RBR with the organic pattern OPR, the subsequent process of forming the color filter layer CFL can become easier, and the thickness uniformity of the color filter layer CFL can be improved (e.g., a substantially uniform thickness of the color filter layer CFL may be provided).

The organic pattern OPR may have a similar shape and size as those of the second conductive layer CDL2 and the third conductive layer CDL3 of the partition wall RBR when viewed from the top (e.g., in a plan view). As described in more detail below, the second conductive layer CDL2 and the third conductive layer CDL3 are etched using the organic pattern OPR as a mask, so that the organic pattern OPR, the second conductive layer CDL2 and the third conductive layer CDL3 may have similar shapes and sizes when viewed from the top (e.g., in a plan view). As shown in FIG. 14, the sides of the organic pattern OPR may protrude from the sides of the second conductive layer CDL2 and the sides of the third conductive layer CDL3.

The organic pattern OPR may include an organic material. The organic material may be, for example, a negative photoresist. The negative photoresist, unlike a positive photoresist, can prevent or reduce the likelihood of problems such as decomposition by light, even if (e.g., when) the negative photoresist remains in the display device 10 in a chemically stable state after the photo process.

According to one or more embodiments, the organic pattern OPR may include a blue colorant to improve the reflectance of external light.

In such embodiments, by leaving the negative photoresist as part of the display device 10 after using it during the photo process and forming it as the organic pattern OPR, the steps of the partition wall RBR are filled with it and flattened, thereby improving the thickness uniformity of the color filter layer CFL. For example, the negative photoresist can serve two functions when it is used as the organic pattern OPR. The first is to prevent or reduce the degradation of the display device 10 as may be caused by light, as the negative photoresist will remain in a chemically stable state in the organic pattern OPR. Second, by filling the steps of the partition wall RBR, the organic pattern OPR helps improve the uniformity of the color filter layer CFL by providing a flatter surface on which to provide the color filter layer CFL.

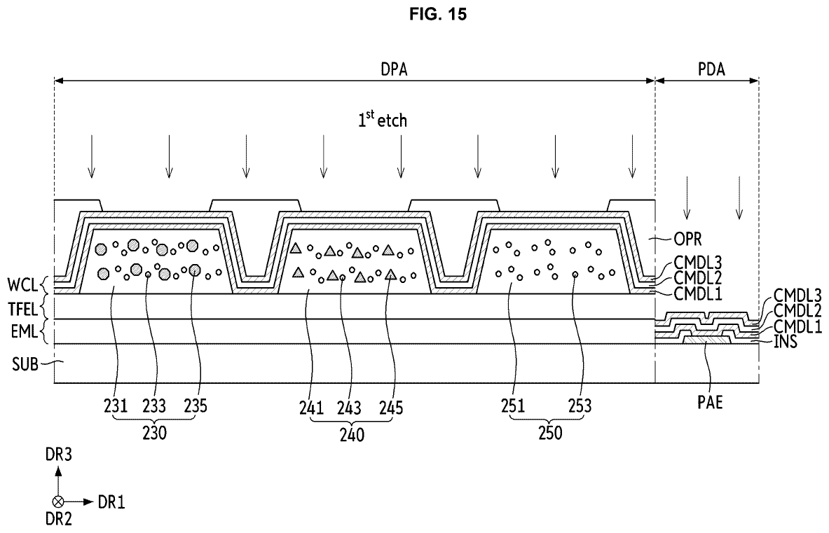

FIGS. 15 to 18 are cross-sectional views showing processing steps of a method for fabricating a display device according to one or more embodiments of the present disclosure. FIGS. 15 to 18 show a method for fabricating a display device according to one or more embodiments shown in FIGS. 13 and 14. In the following description, redundant descriptions may not be provided.

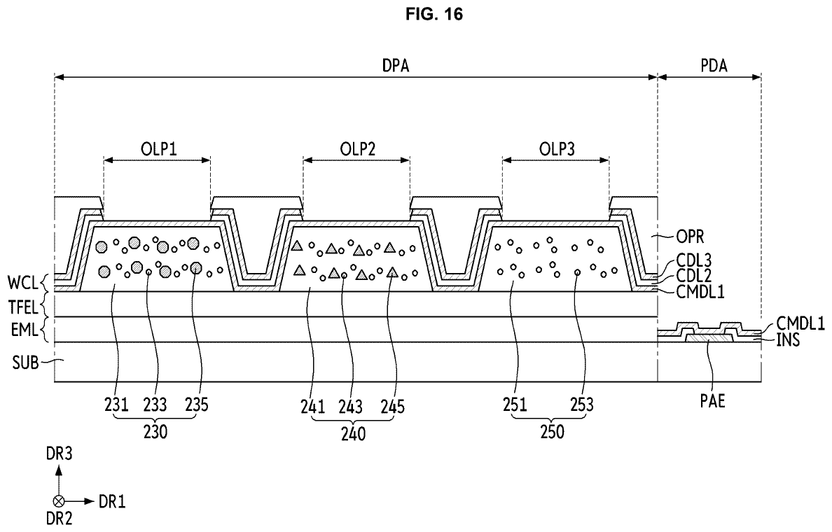

Referring to FIGS. 15 and 16, a substrate SUB is prepared. On the substrate SUB, a light-emitting element layer EML and a thin-film encapsulation layer TFEL may be provided in a display area DPA, and a pad electrode PAE and a pad insulating layer INS may be provided in a pad area PDA.

Subsequently, a first wavelength conversion pattern 230, a second wavelength conversion pattern 240 and a light-transmitting pattern 250 are formed on the thin-film encapsulation layer TFEL. Subsequently, a first conductive material layer CMDL1, a second conductive material layer CMDL2, and a third conductive material layer CMDL3 are sequentially stacked on the substrate SUB.

Subsequently, an organic pattern OPR is formed on the third conductive material layer CMDL3. The organic pattern OPR may be formed in the display area DPA, and may be formed between adjacent ones of the first wavelength conversion pattern 230, the second wavelength conversion pattern 240, and the light-transmitting pattern 250. The organic pattern OPR may be a negative photoresist pattern.

Subsequently, the second conductive material layer CMDL2 and the third conductive material layer CMDL3 are subject to first etching using the organic pattern OPR as a mask. The second conductive material layer CMDL2 and the third conductive material layer CMDL3 are etched together by the first etching (1^{st} etch) and the second conductive layer CDL2 and the third conductive layer CDL3 are formed. In one or more embodiments, in the first etching (1^{st} etch), the second conductive material layer CMDL2 and the third conductive material layer CMDL3 arranged in the pad area PDA are all etched and removed. The second conductive layer CDL2 and the third conductive layer CDL3 (e.g., openings in the second conductive layer CDL2 and the third conductive layer CDL3) form and/or define first to third light-output portions OLP1, OLP2 and OLP3 that expose the first conductive material layer CMDL1 thereunder.

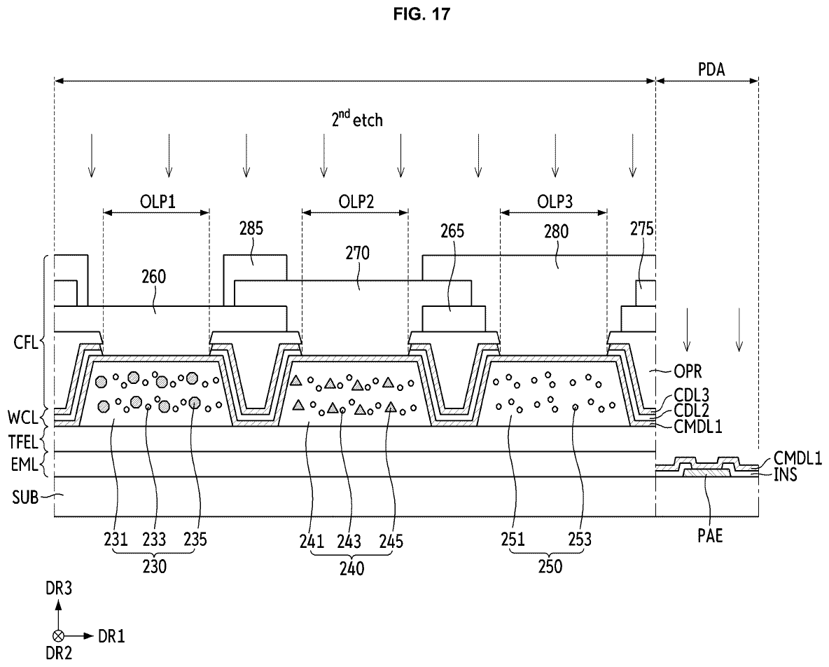

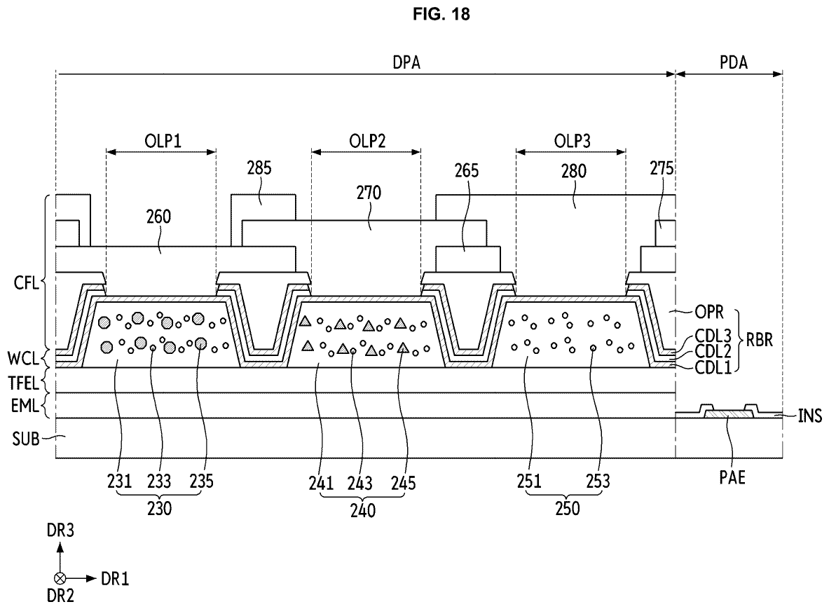

Subsequently, referring to FIGS. 17 and 18, a color filter layer CFL is formed in the display area DPA. For example, a first color filter 260 and a first color pattern 265, a second color filter 270 and a second color pattern 275, and a third color filter 280 and a third color pattern 285 are sequentially formed on the first conductive material layer CMDL1 and the organic pattern OPR. The thickness uniformity of the color filter layer CFL can be improved (e.g., a substantially uniform thickness may be provided) by filling the steps of the partition wall RBR with the organic pattern OPR.

Subsequently, the first conductive material layer CMDL1 formed in the non-display area including the pad area PDA is subjected to second etching (2^{nd} etch). The second etching (2^{nd} etch) may use a second etchant capable of etching the first conductive material layer CMDL1. In the second etching process, the color filter layer CFL formed in the display area DPA works as a mask, so that the first conductive material layer CMDL1 and the third conductive layer CDL3 arranged in the display area DPA are not etched. In contrast, the first conductive material layer CMDL1 arranged in the pad area PDA where the color filter layer CFL is not formed may be removed to expose the pad electrode PAE. In one or more embodiments, because the color filter layer CFL may partially extend (e.g., part of the color filter layer CFL may extend) to the non-display area NDA around the display area DPA, the first conductive material layer CMDL1 masked by the color filter layer CFL remains without being etched. Accordingly, the first conductive material layer CMDL1 that is not removed in the second etching process (2^{nd} etch) is formed into the first conductive layer CDL1.

Through the second etching process, the partition wall RBR is formed by the sequentially stacking of the first conductive layer CDL1, the second conductive layer CDL2 and the third conductive layer CDL3, and the wavelength conversion layer WCL including the first wavelength conversion pattern 230, the second wavelength conversion pattern 240, the light-transmitting pattern 250, the organic pattern OPR and the partition wall RBR can be fabricated. The first conductive layer CDL1 of the partition wall RBR may work as a capping layer for protecting the first wavelength conversion pattern 230, the second wavelength conversion pattern 240 and the light-transmitting pattern 250, thereby preventing or reducing the likelihood of the first wavelength conversion pattern 230, the second wavelength conversion pattern 240 and the light-transmitting pattern 250 being damaged. In one or more embodiments, the organic pattern OPR remains after the first etching process to fill the steps of the partition wall RBR, thereby improving the thickness uniformity of the color filter layer CFL.

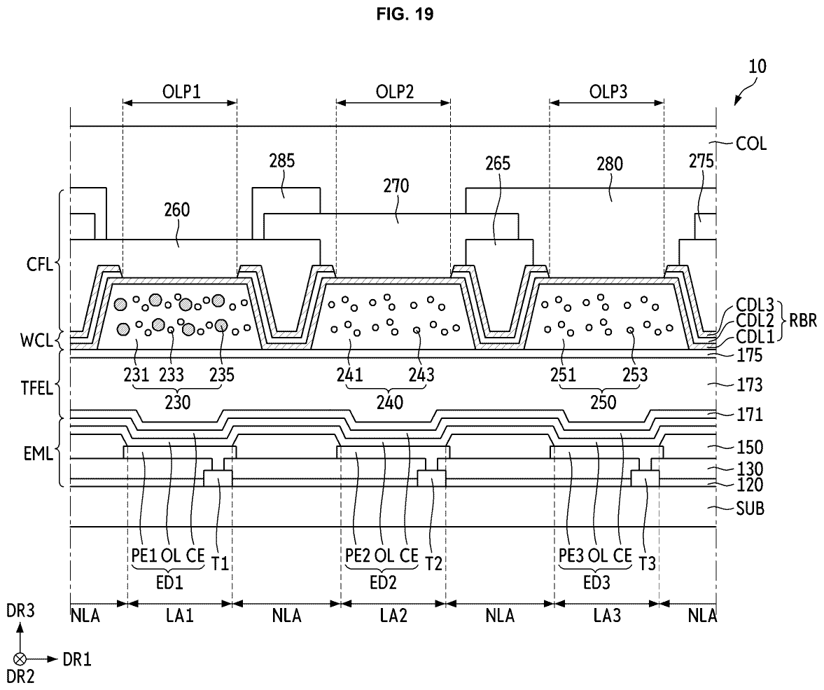

FIG. 19 is a cross-sectional view showing a display device according to one or more embodiments of the present disclosure.

FIG. 19 is different from the above-described embodiments of FIGS. 5 to 18 in that second wavelength shifters 245 are not provided in a second wavelength conversion pattern 240.

Light-emitting elements ED1, ED2 and ED3 of the light-emitting element layer EML may be to emit light of a second color and light of a third color as the source light. For example, an emissive layer OL of each of the light-emitting elements ED1, ED2 and ED3 may be to emit source light in which green light and blue light are mixed.

The second wavelength conversion pattern 240 may include a second base resin 241 and second scatterers 243 dispersed in the second base resin 241. The second wavelength conversion pattern 240 may be to transmit source light output from below as the second wavelength shifters 245 are not provided. In such embodiments, the second wavelength conversion pattern 240 may be to transmit the source light in which the light of the second color and the light of the third color are mixed. The source light having transmitted the second wavelength conversion pattern 240 is incident on the second color filter 270 so that only the light of the second color is transmitted while the light of the third color is blocked, reduced, and/or absorbed, so that the light of the second color can be finally output.

According to such embodiments, the second wavelength conversion pattern 240 may include a base resin and scatterers and may be formed in substantially the same manner as the light-transmitting pattern 250. Accordingly, the second wavelength conversion pattern 240 and the light-transmitting pattern 250 can be performed by a photo process using a mask, thereby reducing the number of masks.

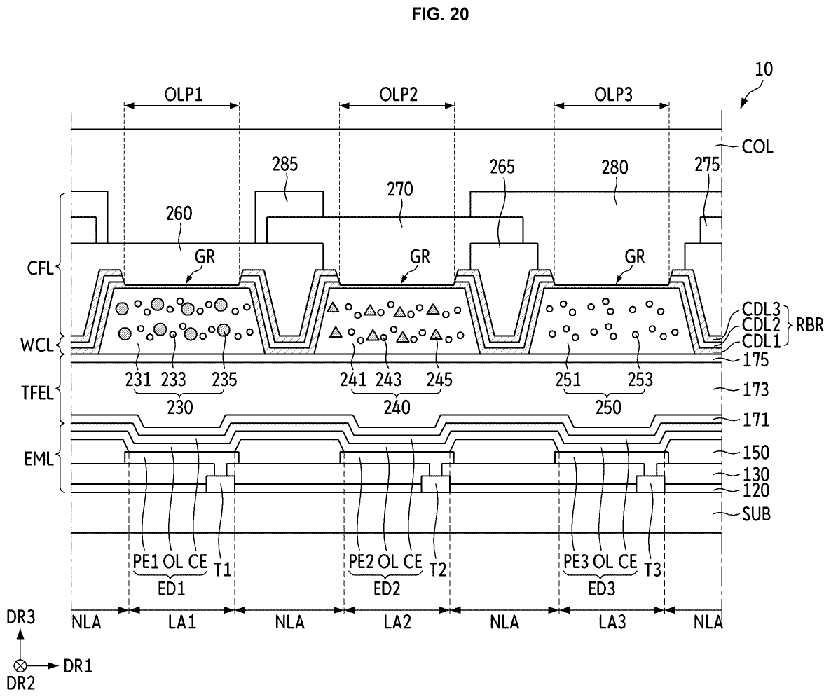

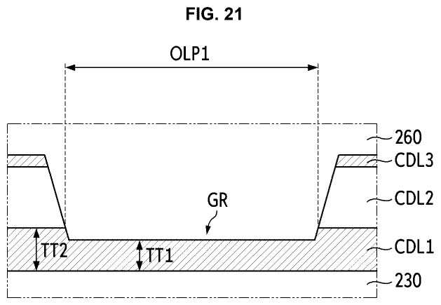

FIG. 20 is a cross-sectional view showing a display device according to one or more embodiments of the present disclosure. FIG. 21 is a cross-sectional view showing the partition wall of FIG. 20, according to one or more embodiments of the present disclosure.

FIGS. 20 and 21 are different from the above-described embodiments shown in FIGS. 5 to 19 in that grooves GR are formed in a first conductive layer CDL1.

A partition wall RBR may include a first conductive layer CDL1, a second conductive layer CDL2 and a third conductive layer CDL3. The first conductive layer CDL1 may include grooves GR. The grooves GR may be formed in line with (may overlap) the light-emitting areas LA1, LA2 and LA3 and the light-output portions OLP1, OLP2 and OLP3, respectively. The grooves GR may not overlap the non-light-emitting area NLA, the second conductive layer CDL2, and the third conductive layer CDL3.

The grooves GR may be formed in a concave shape from the upper surface of the first conductive layer CDL1 toward the substrate SUB. The sides of the grooves GR may be aligned and coordinated with those of the second conductive layer CDL2 and the third conductive layer CDL3. The size (e.g., width or area) of the grooves GR may be smaller than the size (e.g., width or area) of the light-output portions OLP1, OLP2 and OLP3, and in one or more embodiments, may be substantially equal to the size (e.g., width or area) of the light-output portions OLP1, OLP2 and OLP3.

According to one or more embodiments of the present disclosure, the thickness of the first conductive layer CDL1 may vary depending on the location. For example, as shown in FIG. 21, the thickness TT2 of a portion of the first conductive layer CDL1 that overlaps the second conductive layer CDL2 and the third conductive layer CDL3 may be greater than the thickness TT1 of another portion of the first conductive layer CDL2 that does not overlap the second conductive layer CDL2 and the third conductive layer CDL3.

The grooves GR of the first conductive layer CDL1 may be formed by overly etching the first conductive material layer after the third conductive material layer and the second conductive material layer are etched in the first etching process of the above-described method. The grooves GR of the first conductive layer CDL1 reduce the thickness of the first conductive layer CDL1, to improve the transmittance of the first conductive layer CDL1.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Further, the use of “may” when describing embodiments of the present disclosure refers to “one or more embodiments of the present disclosure. ”

As used herein, the term “substantially,” “approximately,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within ±30%, 20%, 10%, 5% of the stated value.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The display device, electronic device, device for manufacturing the display device, and/or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. It is to be understood that the foregoing is an illustration of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a substrate;
a light-emitting element layer on the substrate and defining a plurality of light-emitting areas and a non-light-emitting region;
a thin-film encapsulation layer on the light-emitting element layer;
a wavelength conversion layer on the thin-film encapsulation layer and comprising a first wavelength conversion pattern, a second wavelength conversion pattern, a light-transmitting pattern, and a partition wall; and
a color filter layer on the wavelength conversion layer,
wherein the partition wall comprises a first conductive layer, a second conductive layer and a third conductive layer sequentially stacked on one another, and
wherein the first conductive layer overlaps the light-emitting areas and the non-light-emitting area, and the second conductive layer and the third conductive layer each overlap the non-light-emitting area.

2. The display device of claim 1, wherein the first conductive layer continuously covers the first wavelength conversion pattern, the second wavelength conversion pattern, and the light-transmitting pattern.

3. The display device of claim 2, wherein the first conductive layer is in contact with the thin-film encapsulation layer in the non-light-emitting area.

4. The display device of claim 1, wherein the second conductive layer overlaps the plurality of light-emitting areas and comprises openings that define a plurality of light-output portions exposing the first conductive layer.

5. The display device of claim 4, wherein the third conductive layer does not overlap the light-output portions or the light-emitting areas.

6. The display device of claim 1, wherein each of the first conductive layer and the third conductive layer comprises at least one of ITO, IZO, ZnO, ITZO, or indium oxide.

7. The display device of claim 1, wherein the second conductive layer comprises at least one of silver, magnesium, aluminum, platinum, lead, gold, nickel, neodymium, iridium, chromium, lithium, or calcium.

8. The display device of claim 1, wherein a thickness of the first conductive layer is in a range of about 800 Å to about 1,350 Å.

9. The display device of claim 1, wherein a thickness of the first conductive layer is larger than a thickness of the third conductive layer.

10. The display device of claim 1, further comprising:
an organic pattern between the third conductive layer and the color filter layer,
wherein a side of the organic pattern protrudes outwardly from a side of the third conductive layer.

11. The display device of claim 1, wherein the first wavelength conversion pattern is to convert source light emitted from the light-emitting element layer into light of a first color, the second wavelength conversion pattern is to convert the source light into light of a second color, and the light-transmitting pattern is to transmit the source light at it is.

12. A display device comprising:
a substrate;
a light-emitting element layer on the substrate and defining a plurality of light-emitting areas and a non-light-emitting region;
a thin-film encapsulation layer on the light-emitting element layer;
a wavelength conversion layer on the thin-film encapsulation layer and comprising a first wavelength conversion pattern, a second wavelength conversion pattern, a light-transmitting pattern, and a partition wall; and
a color filter layer on the wavelength conversion layer,
wherein the partition wall comprises a first conductive layer, a second conductive layer and a third conductive layer sequentially stacked on one another, and
wherein the first conductive layer is in the light-emitting areas and the non-light-emitting area, and comprises grooves overlapping the light-emitting areas, and the second conductive layer and the third conductive layer do not overlap the grooves.

13. The display device of claim 12, wherein the second conductive layer and the third conductive layer are between adjacent ones of the first wavelength conversion pattern, the second wavelength conversion pattern and the light transmitting pattern, and do not overlap the light-emitting areas and do overlap the non-light-emitting area.

14. The display device of claim 12, wherein the grooves of the first conductive layer do not overlap the second conductive layer and the third conductive layer.

15. The display device of claim 12, wherein a thickness of a portion of the first conductive layer overlapping the second and third conductive layers is greater than a thickness of another portion of the first conductive layer not overlapping the second and third conductive layers.

16. The display device of claim 12, wherein the first conductive layer continuously covers the first wavelength conversion pattern, the second wavelength conversion pattern, and the light-transmitting pattern.

17. An electronic device comprising:
a display device comprising:
a substrate;
a light-emitting element layer on the substrate and defining a plurality of light-emitting areas and a non-light-emitting region;
a thin-film encapsulation layer on the light-emitting element layer;
a wavelength conversion layer on the thin-film encapsulation layer and comprising a first wavelength conversion pattern, a second wavelength conversion pattern, a light-transmitting pattern, and a partition wall; and
a color filter layer on the wavelength conversion layer,
wherein the partition wall comprises a first conductive layer, a second conductive layer and a third conductive layer sequentially stacked on one another, and
wherein the first conductive layer overlaps the light-emitting areas and the non-light-emitting area, and the second conductive layer and the third conductive layer each overlap the non-light-emitting area.

18. The electronic device of claim 17, wherein the electronic device is a smart phone, a mobile phone, a tablet PC, a personal digital assistant (PDA), a portable multimedia player (PMP), a television set, a game machine, a wristwatch-type electronic device, a head-mounted display, a personal computer monitor, a laptop computer, a car navigation system, a car instrument cluster, a digital camera, a camcorder, an outdoor billboard, an electronic billboard, a medical apparatus, a home appliance or an Internet of things (IoT) device.

19. The electronic device of claim 17, wherein the first conductive layer continuously covers the first wavelength conversion pattern, the second wavelength conversion pattern, and the light-transmitting pattern.

20. The electronic device of claim 19, wherein the first conductive layer is in contact with the thin-film encapsulation layer in the non-light-emitting area.
